(19) United States
(12) Patent Application Publication
(10) Pub. No.: US 2025/0338484 A1
(43) Pub. Date: Oct. 30, 2025

(54) SEMICONDUCTOR DEVICE AND METHOD OF FABRICATING A SEMICONDUCTOR

(71) Applicant: Samsung Electronics Co., Ltd., Suwon-si (KR)

(72) Inventors: Keunnam KIM, Suwon-si (KR); Hongjun LEE, Suwon-si (KR); Yong Kwan KIM, Suwon-si (KR); Hui-Jung KIM, Suwon-si (KR)

(73) Assignee: Samsung Electronics Co., Ltd., Suwon-si (KR)

(21) Appl. No.: 18/954,692

(22) Filed: Nov. 21, 2024

(30) Foreign Application Priority Data
Apr. 29, 2024 (KR) 10-2024-0056898

(51) Int. Cl. H10B 12/00

(52) U.S. Cl. CPC H10B 12/482; H10B 12/09; H10B 12/50

(57) ABSTRACT

A semiconductor device includes a substrate including a cell region and a peripheral region, word lines extending in a first direction on the cell region, bit lines extending across the word lines in a second direction, the second direction intersecting the first direction, and including first bit lines and second bit lines arranged alternately in the first direction, each of the first bit lines including a bit line tail portion extending in the second direction, and a bit line hammer portion connected to an end of the bit line tail portion, a spacer pattern surrounding the bit line hammer portion on the peripheral region, a bit line protection pattern surrounding each end of the second bit lines in the cell region, and a bit line spacer extending in the second direction along each side surface of the bit lines.

### CROSS-REFERENCE TO RELATED APPLICATIONS

This U.S. non-provisional patent application claims priority under 35 U.S.C. § 119 to Korean Patent Application No. 10-2024-0056898, filed on Apr. 29, 2024, in the Korean Intellectual Property Office, the entire contents of which are hereby incorporated by reference.

### BACKGROUND OF THE INVENTION

The inventive concepts relate to a semiconductor device and a method of fabricating the same, and more specifically, relating to a semiconductor device including a metal wiring.

Semiconductor devices have desired characteristics, such as miniaturization, multi functions, and/or low manufacturing costs and are, thus, regarded with much interest as a core part in electronics industry. Semiconductor devices may be classified into semiconductor memory devices for storing data, semiconductor devices for processing data, and hybrid semiconductor devices including a memory element and a processing element (e.g. a logic element).

Recently, to obtain electronic products having high speed and low power consumption, the semiconductor devices embedded in the electronic products are usually required to have high operating speed and/or low operating voltage. As a result, semiconductor devices have become more highly integrated. Accordingly, various research has been conducted to improve electrical characteristics and reliability of semiconductor devices while fabricating smaller features of the semiconductor device.

### SUMMARY

Some example embodiments of the inventive concepts are to provide a semiconductor device, and/or a method of fabricating a semiconductor device, with improved operating characteristics and reliability.

Some example embodiments of the inventive concepts are to provide a method of fabricating a semiconductor device that may improve yield.

A semiconductor device according to some example embodiments of the inventive concepts may include a substrate including a cell region and a peripheral region, word lines extending in a first direction on the cell region, bit lines extending across the word lines in a second direction, the second direction intersecting the first direction, and including first bit lines and second bit lines arranged alternately in the first direction, each of the first bit lines including a bit line tail portion extending in the second direction, and a bit line hammer portion connected to an end of the bit line tail portion, a spacer pattern surrounding the bit line hammer portion on the peripheral region, a bit line protection pattern surrounding each end of the second bit lines in the cell region, and a bit line spacer extending in the second direction along each side surface of the bit lines. The bit line spacer extends on side surfaces of the spacer pattern and the bit line protection pattern in the second direction, and a width of the bit line protection pattern in the first direction is smaller than a maximum width of the spacer pattern in the first direction.

A semiconductor device according to some example embodiments of the inventive concepts may include a substrate including a cell region and a peripheral region, word lines extending in a first direction on the cell region, bit lines extending across the word lines in a second direction, the second direction intersecting the first direction, and including first bit lines and second bit lines arranged alternately in the first direction, each of the first bit lines including a bit line hammer portion on the peripheral region, a first capping pattern surrounding each of the first bit lines on the peripheral region, a second capping pattern surrounding each of the second bit lines on the cell region, a spacer pattern on the first capping pattern in the peripheral region and surrounding an end of the bit line hammer portion, and a bit line protection pattern on the second capping pattern in the cell region and surrounding each end of the second bit lines. The first capping pattern and the second capping pattern include a first same material, the bit line protection pattern and the spacer pattern include a second same material, and the bit line protection pattern is offset from the spacer pattern in the second direction.

A semiconductor device according to some example embodiments of the inventive concepts may include a substrate including a cell region and a peripheral region, word lines extending in a first direction on the cell region, bit lines extending across the word lines in a second direction, the second direction intersecting the first direction, and including first bit lines and second bit lines arranged alternately in the first direction, each of the first bit lines including a bit line tail portion extending in the second direction, and a bit line hammer portion connected to an end of the bit line tail portion, bit line contacts on the cell region and connected to corresponding bit lines among the bit lines, a first capping pattern surrounding each of the first bit lines on the peripheral region, a second capping pattern surrounding each of the second bit lines on the cell region, a spacer pattern on the first capping pattern in the peripheral region and surrounding an end of the bit line hammer portion, a bit line protection pattern on the second capping pattern in the cell region and surrounding each end of the second bit lines, and a bit line spacer extending in the second direction along each side surface of the bit lines. The bit line protection pattern is offset from the spacer pattern in the second direction, a width of the bit line protection pattern in the first direction is smaller than a width of the spacer pattern in the first direction, and a width of the bit line protection pattern in the second direction is smaller than a width of the second capping pattern in the second direction.

### BRIEF DESCRIPTION OF THE DRAWINGS

Various example embodiments will be more clearly understood from the following brief description taken in conjunction with the accompanying drawings. The accompanying drawings represent non-limiting, example embodiments as described herein.

FIG. 1 is a plan view illustrating a semiconductor device according to various example embodiments of the inventive concepts.

FIG. 2 is a cross-sectional view taken along line A-A′ of FIG. 1.

FIG. 3 is a cross-sectional view taken along line B-B′ in FIG. 1.

FIG. 4 is an enlarged view of region ‘M’ in FIG. 1.

FIGS. 5, 7, 9, 11, 13, and 15 are plan views illustrating a fabricating process of a semiconductor device according to various example embodiments of the inventive concepts.

FIGS. 6A, 8A, 10A, 12A, 14A, and 16A, are cross-sectional views taken along line A-A′ of FIGS. 5, 7, 9, 11, 13, and 15, respectively.

FIGS. 6B, 8B, 10B, 12B, 14B, and 16B, are cross-sectional views taken along line B-B′ of FIGS. 5, 7, 9, 11, 13, and 15 respectively.

FIG. 17 is a plan view illustrating a semiconductor device according to some embodiments of the inventive concept.

FIG. 18 is a cross-sectional view taken along line A-A′ of FIG. 17.

FIG. 19 is a cross-sectional view taken along line B-B′ of FIG. 17.

FIG. 20 is an enlarged view of region ‘M’ in FIG. 17.

FIGS. 21, 23, 25, 27, 29, 31, 33, and 35 are plan views illustrating a fabricating process of a semiconductor device according to some example embodiments of the inventive concepts.

FIGS. 22A, 24A, 26A, 28A, 30A, 32A, 34A, and 36A are cross-sectional views along A-A′ of FIGS. 21, 23, 25, 27, 29, 31, 33, and 35 respectively.

FIGS. 22B, 24B, 26B, 28B, 30B, 32B, 34B, and 36B are cross-sectional views along B-B′ of FIGS. 21, 23, 25, 27, 29, 31, 33, and 35 respectively.

FIGS. 37, 39, 41, and 43 are plan views illustrating a fabricating process of a semiconductor device according to some embodiments of the inventive concept, respectively.

FIGS. 38A, 40A, 42A, and 44A are cross-sectional views taken along line A-A′ of FIGS. 37, 39, 41, and 43, respectively.

FIGS. 38B, 40B, 42B, and 44B are cross-sectional views taken along line B-B′ of FIGS. 37, 39, 41, and 43, respectively.

### DETAILED DESCRIPTION

Hereinafter, the inventive concepts will be described in detail by explaining various example embodiments of the inventive concepts with reference to the accompanying drawings.

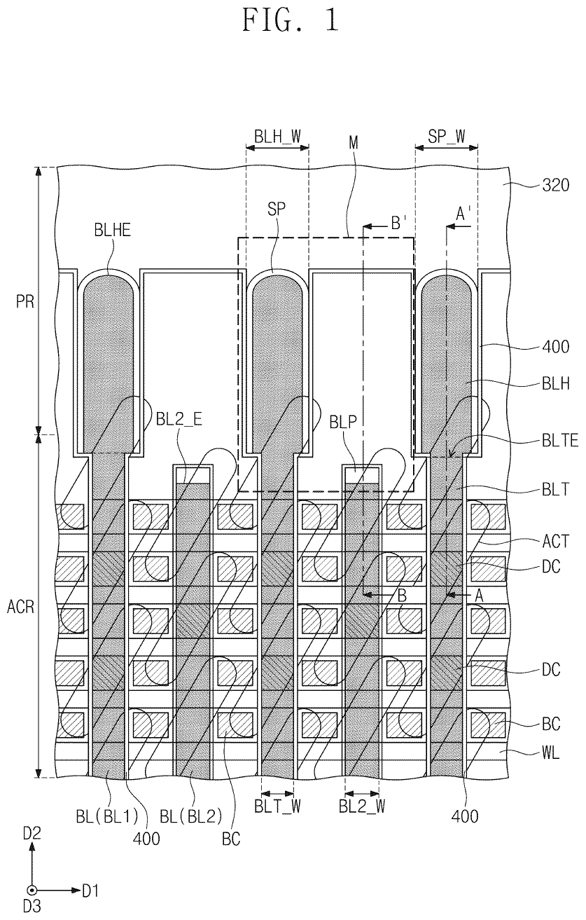

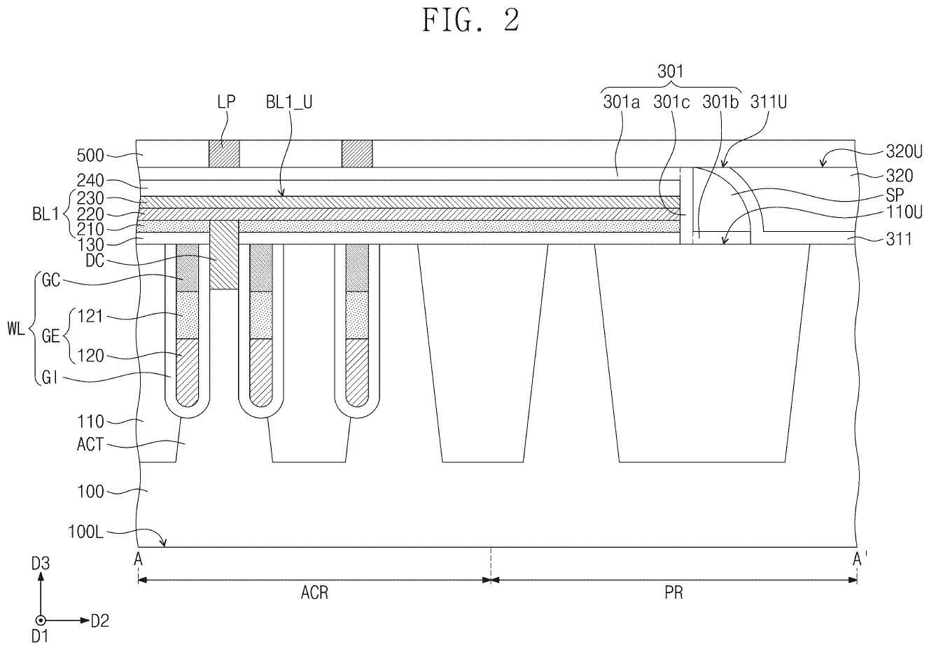

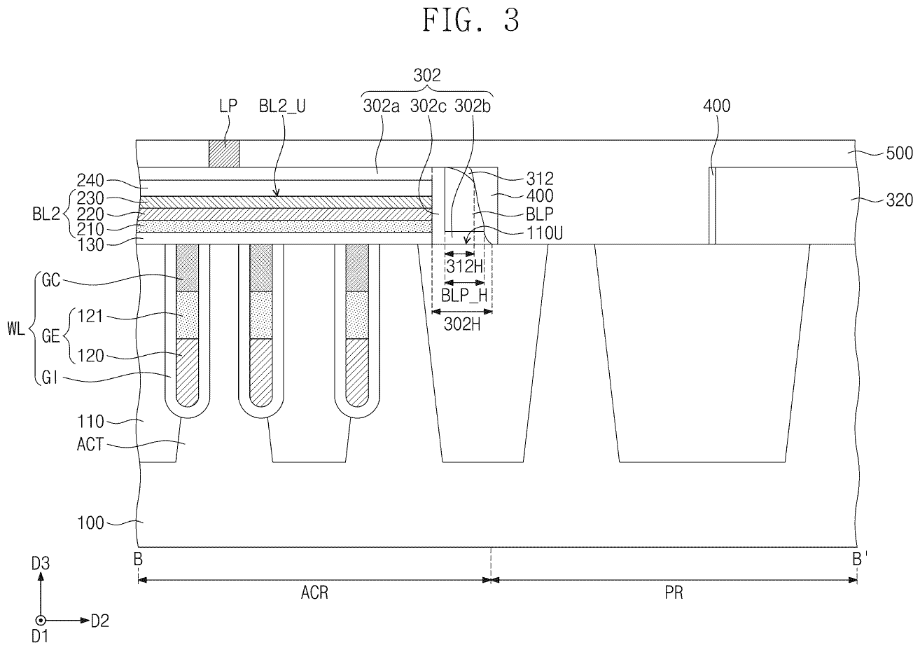

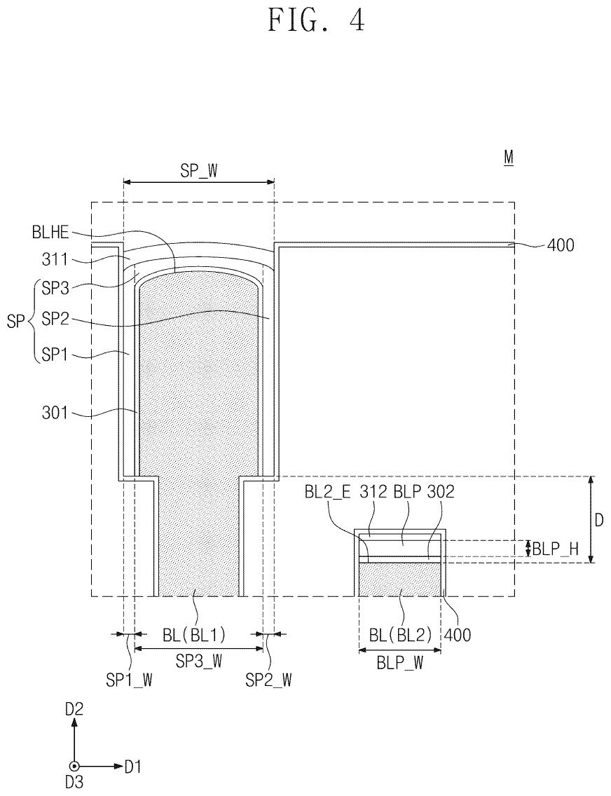

FIG. 1 is a plan view illustrating a semiconductor device according to various example embodiments of the inventive concepts. FIG. 2 is a cross-sectional view taken along line A-A′ of FIG. 1. FIG. 3 is a cross-sectional view taken along line B-B′ in FIG. 1. FIG. 4 is an enlarged view of region ‘M’ in FIG. 1.

Referring to FIGS. 1 to 3, a substrate 100 may be provided. The substrate 100 may be a semiconductor substrate, for example, a silicon substrate, a germanium substrate, or a silicon-germanium substrate. However, example embodiments are not limited thereto. The substrate may include a cell region ACR and a peripheral region PR.

Active patterns ACT may be disposed on the cell region ACR of the substrate 100. The active patterns ACT may be spaced apart from each other in a first direction D1 and a second direction D2 parallel to a lower surface 100L of the substrate 100. The first direction D1 and the second direction D2 may intersect each other. Each of the active patterns ACT may be parallel to the lower surface 100L of the substrate 100 and may have a bar shape extending in a third direction D3 that intersects the first direction D1 and the second direction D2. Each of the active patterns ACT may be a portion of the substrate 100 that protrudes from the substrate 100 in the third direction D3 perpendicular to the lower surface 100L of the substrate 100. The active patterns ACT may be partially disposed on the peripheral region PR.

A device isolation layer 110 may be disposed on the substrate 100 to define the active patterns ACT. The device isolation layer 110 may be disposed on the cell region ACR and the peripheral region PR of the substrate 100 and may be interposed between the active patterns ACT. For example, the device isolation layer 110 may include silicon oxide, silicon nitride, and/or silicon oxynitride. However, example embodiments are not limited thereto.

Word lines WL may be disposed on the cell region ACR of the substrate 100 and may cross the active patterns ACT and the device isolation layer 110. The word lines WL may extend in the first direction D1 and may be spaced apart in the first direction D1. The word lines WL may be buried word lines disposed in the active patterns ACT and the device isolation layer 110.

Each of the word lines WL may include a gate electrode GE penetrating the active patterns ACT and upper portions of the device isolation layer 110, and a gate dielectric pattern GI interposed between the gate electrode GE and the active patterns ACT and between the gate electrode GE and the device isolation layer 110, and a gate capping pattern GC on an upper surface of the gate electrode GE. The upper surface of the gate capping pattern GC may be substantially coplanar with upper surfaces of the active patterns ACT. For example, the upper surface of the gate capping pattern GC may be positioned at the same height as the upper surfaces of the active patterns ACT.

The gate electrode GE may include a first conductive layer 120 and a second conductive layer 121. As an example, the first conductive layer 120 and the second conductive layer 121 are formed of a doped semiconductor material (e.g., doped silicon, doped germanium, etc.), a conductive metal nitride (e.g., titanium nitride, tantalum nitride, etc.), a metal (e.g., tungsten, titanium, tantalum, etc.), and a metal-semiconductor compound (e.g., tungsten silicide, cobalt silicide, titanium silicide, etc.). However, example embodiments are not limited thereto. The first conductive layer 120 and the second conductive layer 121 may include different materials (e.g., materials having different work functions). For example, the gate dielectric pattern GI may include a silicon oxide layer, a silicon nitride layer, and/or a silicon oxynitride layer. For example, the gate capping pattern GC may include a silicon oxide layer, a silicon nitride layer, and/or a silicon oxynitride layer. However, example embodiments are not limited thereto.

An insulating layer 130 may be disposed on the cell region ACR and the peripheral region PR of the substrate 100, and may cover the active patterns ACT, the device isolation layer 110, and the word lines WL. For example, the insulating layer 130 may include a single layer or a multilayer including at least one of a silicon oxide layer, a silicon nitride layer, and a silicon oxynitride layer. However, example embodiments are not limited thereto.

Bit lines BL may be disposed on the active cell region ACR of the substrate 100 and on the insulating layer 130. The bit lines BL may cross the word lines WL. The bit lines BL may extend in the second direction D2 and may be spaced apart from each other in the first direction D1. Each of the bit lines may include a polysilicon pattern 210, an ohmic pattern 220, and a metal-containing pattern 230 that are sequentially stacked on the insulating layer 130. However, example embodiments are not limited thereto. The bit lines BL may include first bit lines BL1 and second bit lines BL2 disposed alternately in the first direction D1.

The first bit lines BL1 may include a bit line tail portion BLT extending in the second direction D2 and a bit line hammer portion BLH connected to an end BLTE of the bit line tail portion BLT. The bit line tail portion BLT may be disposed on the cell region ACR, and the bit line hammer portion BLH may be disposed on the peripheral region PR. A width BLH_W of the bit line hammer portion BLH in the first direction D1 may be greater than a width BLT_W of the bit line tail portion BLT in the first direction D1. An end BLHE of the bit line hammer portion BLH may have a curved shape when viewed in a plan view.

Each of the second bit lines BL2 may be offset from the bit line hammer portion BLH in the second direction D2. Furthermore, each of the second bit lines BL2 may be offset from the end BLTE of the bit line tail portion BLT in the second direction D2. A width BL2_W of each of the second bit lines BL2 in the first direction D1 may be smaller than the width BLH_W of the bit line hammer portion BLH in the first direction D1.

A lower insulating layer 240 may be disposed on an upper surface of each of the bit lines BL. The lower insulating layer 240 may extend in the second direction D2 along the upper surface of the bit lines BL. Among the lower insulating layers 240, the lower insulating layer 240 covering the upper surface BL1_U of the first bit lines BL1 may extend to the cell region ACR and the peripheral region PR. The lower insulating layer 240 covering an upper surface BL1_U of the first bit lines BL1 may be disposed on the bit line tail portion BLT and an upper surface of the bit line hammer portion BLH. Among the lower insulating layers 240, the lower insulating layer 240 covering the upper surface BL2_U of the second bit lines BL2 may be disposed on the cell region ACR.

A first capping pattern 301 may be disposed on the lower insulating layer 240 covering the upper surface BL1_U of each of the first bit lines BL1. The first capping pattern 301 may include a first upper capping pattern 301a, a first lower capping pattern 301b, and a first connection capping pattern 301c connecting the first upper capping pattern 301a and the first lower capping pattern 301b. The first upper capping pattern 301a may be disposed on the lower insulating layer 240, and may be disposed on the cell region ACR and the peripheral region PR. The first lower capping pattern 301b may be disposed on the upper surface 110U of the device isolation layer 110 and may be disposed on the peripheral region PR. The first upper capping pattern 301a and the first lower capping pattern 301b may have a step in the third direction D3. The first connection capping pattern 301c may extend vertically in the third direction D3 to connect the first upper capping pattern 301a and the first lower capping pattern 301b. Referring to FIG. 4, the first capping pattern 301 (e.g., the first connection capping pattern) extend along a side surface and the end BLHE of the bit line hammer portion BLH and may surround (or cover) the side surface and the end BLHE of the bit line hammer portion BLH, when viewed in a plan view. For example, the first capping pattern 301 may be silicon nitride.

A second capping pattern 302 may be disposed on the lower insulating layer 240 covering the second bit lines BL2. The second capping pattern 302 may include a second upper capping pattern 302a, a second lower capping pattern 302b, and a second connection capping pattern 302c connecting the second upper capping pattern 302a and the second lower capping pattern 302b. The second upper capping pattern 302a may be disposed on the lower insulating layer 240 and may be disposed on the cell region ACR. The second lower capping pattern 302b may be disposed on an upper surface 110U of the device isolation layer and may be disposed on the cell region ACR. The second upper capping pattern 302a and the second lower capping pattern 302b may have a step in the third direction D3. The second connection capping pattern 302c may extend vertically in the third direction D3 and connect the second upper capping pattern 302a and the second lower capping pattern 302b.

Referring to FIG. 4, the second capping pattern (e.g., a connected second capping pattern) 302 may extend along each end BL2_E of the second bit lines BL2, and may surround (or cover) each end BL2_E of the second bit lines BL2, when viewed in a plan view. The first capping pattern 301 and the second capping pattern 302 may include the same material. For example, the second capping pattern 302 may be silicon nitride.

A spacer pattern SP may be disposed on the peripheral region PR and on the first capping pattern (e.g., the first lower capping pattern 301b). The spacer pattern SP may surround the first connection capping pattern 301c and the bit line hammer portion BLH. Referring to FIG. 4, an end of the spacer pattern SP may have a curved shape when viewed in a plan view. The spacer pattern SP may include a first portion SP1 and a second portion SP2 facing each other in the first direction D1, and a third portion SP3 extending in the first direction D1 to connect the first portion SP1 and the second portion SP2. The first portion SP1 and the second portion SP2 may respectively surround side surfaces of the bit line hammer portion BLH, and the third portion SP3 may surround the end BLHE of the bit line hammer portion BLH. The third portion SP3 may be referred to as an end of the spacer pattern SP. A width SP1_W of the first portion SP1 in the first direction D1 may be different from a width SP2_W of the second portion SP2 in the first direction D1. The first capping pattern (e.g., the first connection capping pattern 301c) 301 may be interposed between the spacer pattern SP and the bit line hammer portion BLH. For example, the spacer pattern SP may include silicon oxide.

A bit line protection pattern BLP may be disposed on the second capping pattern 302 (e.g., the second lower capping pattern). The bit line protection pattern BLP may be disposed on the second connection capping pattern 302c. The bit line protection pattern BLP may surround each end BL2_E of the second bit lines BL2, and the bit line protection pattern BLP may have various shapes (e.g., circle, triangle, rhombus, etc.) when viewed in a plan view. The bit line protection pattern BLP may be offset from the bit line hammer portion BLH in the second direction D2.

A width BLP_W of the bit line protection pattern BLP in the first direction D1 may be smaller than the maximum width SP_W of the spacer pattern SP in the first direction D1. In this case, the maximum width SP_W of the spacer pattern SP in the first direction D1 may be the sum of widths SP1_W, SP2_W, and SP3_W of the first to third portions SP1, SP2, and SP3 in the first direction D1. Furthermore, the width BLP_W of the bit line protection pattern BLP in the first direction D1 may be smaller than the width SP3_W of the third portion SP3 in the first direction D1.

The width BLP_H of the bit line protection pattern BLP in the second direction D2 may be smaller than a separation distance D between the end BL2_E of the second bit line BL2 and the bit line hammer portion BLH in the second direction D2. The second capping pattern 302 (e.g., the second connection capping pattern 302c) may be interposed between each of the second bit lines BL2 and the bit line protection pattern BLP. The bit line protection pattern BLP may include the same material as the spacer pattern SP, for example, silicon oxide.

A third capping pattern 311 may be disposed on the spacer pattern SP and on the peripheral region PR. The third capping pattern 311 may surround the third portion SP3 of the spacer pattern SP and may be in contact with the first lower capping pattern 301b. For example, the third capping pattern 311 may be silicon nitride.

The spacer pattern SP may be interposed between the first capping pattern 301 and the third capping pattern 311 on the end BLHE of the bit line hammer portion BLH. The third portion SP3 of the spacer pattern SP may be disposed on the end BLHE of the bit line hammer portion BLH, and may be interposed between the first connection capping pattern 301c and the third capping pattern 311 and between the first lower capping pattern 301b and the third capping pattern 311. The first and second portions SP1 and SP2 of the spacer pattern SP may be disposed on side surfaces of the bit line hammer portion BLH and on the first connection capping pattern 301c.

A fourth capping pattern 312 may be disposed on the bit line protection pattern BLP and may be disposed on the cell region ACR. The fourth capping pattern 312 may include the same material as the third capping pattern 311, and may be, for example, silicon nitride. A width 312H of the fourth capping pattern 312 in the second direction D2 may be smaller than the width BLP_H of the bit line protection pattern BLP in the second direction D2, and may be smaller than the width 302H of the second capping pattern 302 in the second direction D2. The width BLP_H of the bit line protection pattern BLP in the second direction D2 may be smaller than the width 302H of the second capping pattern 302 in the second direction D2. The bit line protection pattern BLP may be interposed between the second capping pattern 302 and the fourth capping pattern 312.

A peripheral insulating layer 320 may be disposed on the peripheral region PR and may be in contact with the third capping pattern 311. An upper surface 320U of the peripheral insulating layer 320 may be substantially coplanar with an upper surface 311U of the third capping pattern 311. For example, the peripheral insulating layer 320 may include silicon oxide.

Bit line contacts DC may be disposed below the bit lines BL, respectively, and may be spaced apart from each other in the first direction D1. The bit line contacts DC may be disposed on the cell region ACR. Each of the bit line contacts DC may penetrate the insulating layer 130 and the polysilicon pattern 210, and may be electrically connected to each of the active patterns ACT. An ohmic pattern 220 and a metal-containing pattern 230 may cover upper surfaces of the bit line contacts DC. The bit line contacts DC may include one of a doped semiconductor material (e.g., doped silicon, doped germanium, etc.), conductive metal nitride (e.g., titanium nitride, tantalum nitride, etc.), a metal (e.g., tungsten, titanium, tantalum, etc.), and metal-semiconductor compound (e.g., tungsten silicide, cobalt silicide, titanium silicide, etc.). However, example embodiments are not limited thereto.

A bit line spacer 400 may be disposed on each side surface of the bit lines BL. The bit line spacer 400 may extend in the second direction D2 along the side surfaces of the bit lines BL, respectively. The bit line spacer 400 may extend along the side surfaces of the bit line tail portion BLT and the bit line hammer portion BLH, and may extend along each side surface of the second bit lines BL2. The bit line spacer 400 may surround the spacer pattern SP and may surround the bit line protection pattern BLP. Referring to FIG. 4, the bit line spacer 400 may cover the first and second portions SP1 and SP2 of the spacer pattern SP and side surfaces of the third capping pattern 311, and may cover side surfaces of the second capping pattern 302, the bit line protection pattern BLP, and the fourth capping pattern 312, when viewed in a plan view.

Storage node contacts BC may be disposed between a pair of neighboring bit lines BL and may be spaced apart from each other in the first direction D1. The storage node contacts BC may be disposed on the cell region ACR.

Landing pads LP may be disposed on each of the storage node contacts BC on the active cell region ACR. The landing pads LP may include a metal-containing material such as tungsten. However, example embodiments are not limited thereto.

An upper insulating layer 500 may fill a space between the landing pads LP on the cell region ACR. The upper insulating layer 500 may extend onto the peripheral region PR and cover an upper surface of the peripheral insulating layer 320. For example, the upper insulating layer 500 may include at least one of silicon oxide, silicon nitride, and silicon oxynitride. However, example embodiments are not limited thereto.

Although not illustrated, a capacitor structure may be disposed on the cell region ACR and on the upper insulating layer 500. The capacitor structure may include a plurality of lower electrodes respectively disposed on the landing pads LP, an upper electrode covering the plurality of lower electrodes, and a dielectric layer between each of the plurality of lower electrodes and the upper electrode. The plurality of lower electrodes may include at least one of an impurity-doped polysilicon, a metal nitride layer such as titanium nitride, and a metal layer such as tungsten, aluminum, and copper. The plurality of upper electrodes may include at least one of a polysilicon layer doped with an impurity, a silicon germanium layer doped with an impurity, a metal nitride layer such as a titanium nitride layer, and a metal layer such as tungsten, aluminum, and copper. For example, the dielectric layer may include at least one of a silicon oxide layer, a silicon nitride layer, a silicon oxynitride layer, and a high dielectric layer (e.g., a hafnium oxide layer).

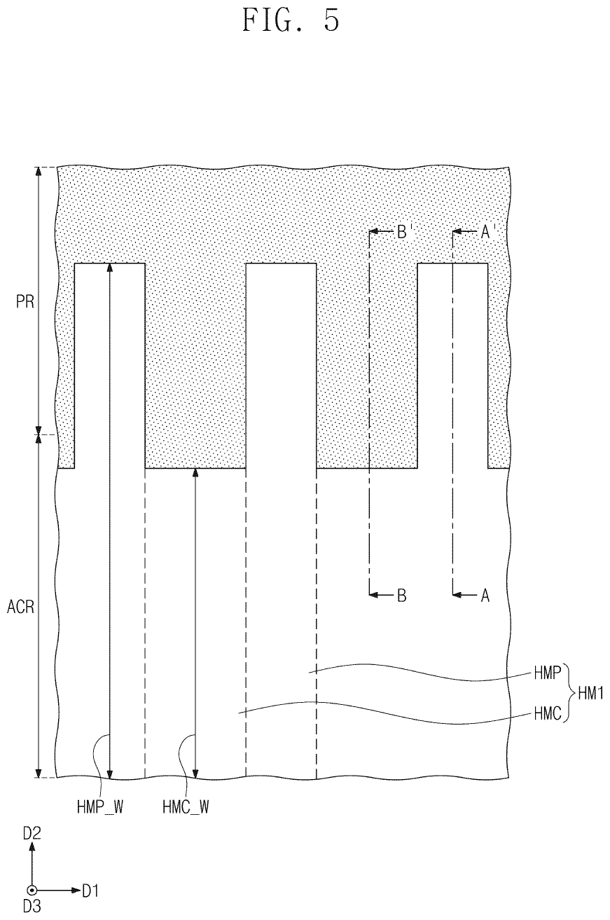

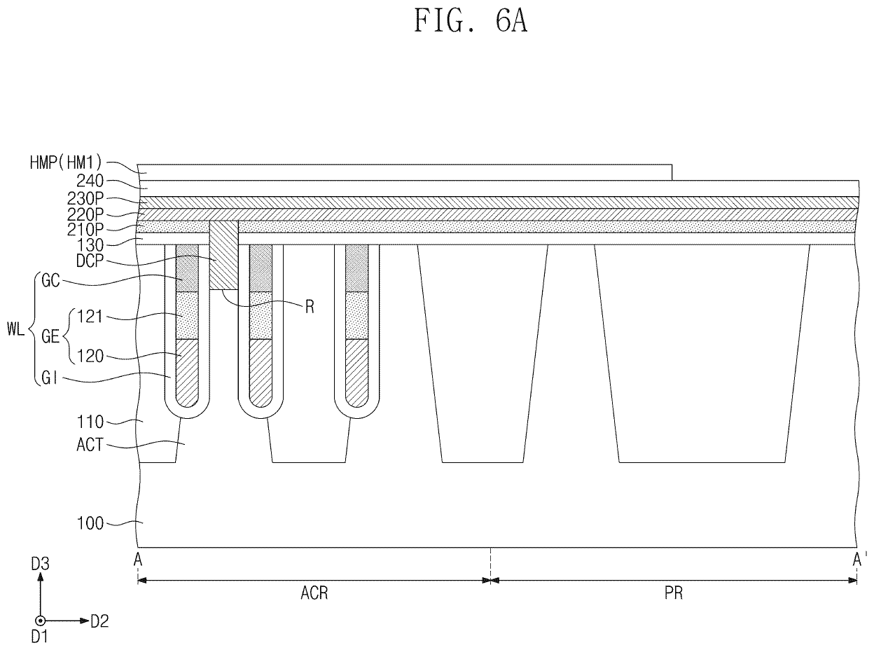

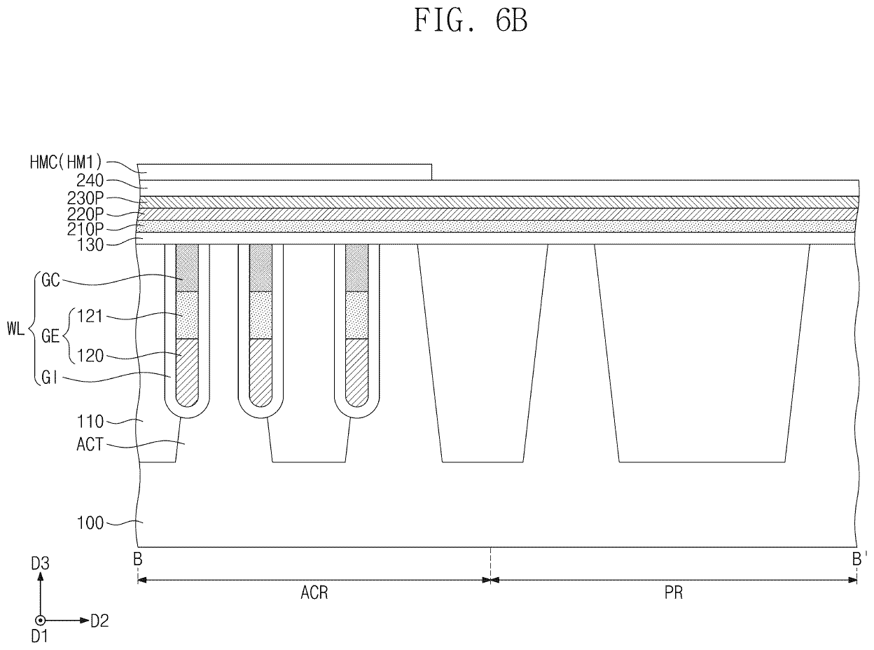

FIGS. 5, 7, 9, 11, 13, and 15 are plan views illustrating a fabricating process of a semiconductor device according to various example embodiments of the inventive concepts. FIGS. 6A, 8A, 10A, 12A, 14A, and 16A are cross-sectional views taken along line A-A′ of FIGS. 5, 7, 9, 11, 13, and 15, respectively. FIGS. 6B, 8B, 10B, 12B, 14B, and 16B are cross-sectional views taken along line B-B′ of FIGS. 5, 7, 9, 11, 13, and 15, respectively. For simplicity of explanation, content that overlaps with the semiconductor devices described with reference to FIGS. 1 to 4 will be omitted.

Referring to FIGS. 5 to 6B, a substrate 100 including a cell region ACR and a peripheral region PR may be provided. Active patterns ACT and a device isolation layer 110 may be formed on the substrate 100, and forming the active patterns ACT may include, for example, forming separation mask patterns on the substrate 100, and etching an upper portion of the substrate 100 using the separation mask patterns as an etch mask. As the upper portion of the substrate 100 is etched, a trench exposing side surfaces of the active patterns ACT may be formed in the substrate 100. A device isolation layer 110 may be formed to fill the trench. Forming the device isolation layer 110 may include, for example, forming a device isolation insulating layer that fills the trench on the substrate 100, and planarizing the device isolation insulating layer until an upper surface of the substrate 100 is exposed.

Word lines WL may be formed on the cell region ACR of the substrate 100 and may cross the active patterns ACT and the device isolation layer 110. The word lines WL may extend in the first direction D1 and may be spaced apart from each other in the second direction D2. Each of the word lines WL may include a gate electrode GE penetrating the active patterns ACT and upper portions of the device isolation layer 110, a gate dielectric pattern GI interposed between the gate electrode GE and the active patterns ACT and between the gate electrode GE and the device isolation layer 110, and a gate capping pattern GC on an upper surface of the gate electrode GE. Forming the gate electrode GE and the gate dielectric pattern GI may include, for example, forming grooves penetrating the active patterns ACT and upper portions of the device isolation layer 110 in the substrate 100, forming a gate dielectric layer covering inner surfaces of the grooves, respectively, forming a gate electrode layer filling each of the grooves, and planarizing the gate dielectric layer and the gate electrode layer until the upper surface of the substrate 100 is exposed. Forming the gate capping pattern GC may include, for example, recessing an upper portion of the gate electrode GE to form an empty region in each of the grooves, forming a gate capping layer that fills the empty region, and planarizing the gate capping layer until the upper surface of the substrate 100 is exposed.

An insulating layer 130 may be formed on the active cell region ACR and the peripheral region PR of the substrate 100, and may cover the active patterns ACT, the device isolation layer 110, and the word lines WL. A polysilicon layer 210P may be formed on the active cell region ACR and the peripheral region PR of the substrate 100, and may be stacked on the insulating layer 130. Recess regions R may be formed to penetrate the insulating layer 130 and the polysilicon layer 210P, and may extend into the active patterns ACT and the device isolation layer 110. Forming the recess regions R may include, for example, forming recess mask patterns on the polysilicon layer 210P that define a region where the recess regions R will be formed, and etching the polysilicon layer 210P, the insulating layer 130, the active patterns ACT, and the device isolation layer 110 using recess mask patterns as an etch mask. After the recess regions R are formed, the recess mask patterns may be removed.

A bit line contact layer DCP may be formed to fill the recess regions R. Forming the bit line contact layer DCP may include, for example, forming the bit line contact layer DCP to fill the recess regions R on the polysilicon layer 210P, and planarizing the bit line contact layer DCP until an upper surface of the polysilicon layer 210P is exposed. Accordingly, the bit line contact layer DCP may be formed locally in the recess regions R.

An ohmic layer 220P, a metal-containing layer 230P, and a lower insulating layer 240 may be formed on the active cell region ACR and the peripheral region PR of the substrate 100, and may be sequentially stacked on the polysilicon layer 210P. The ohmic layer 220P may cover upper surfaces of the polysilicon layer 210P and the bit line contact layer DCP.

A first bit line mask pattern HM1 may be formed on the lower insulating layer 240. The first bit line mask pattern HM1 may include cell mask regions HMC formed on the cell region ACR and peripheral mask regions HMP formed on the cell region CR and the peripheral region PR. The cell mask regions HMC and the peripheral mask regions HMP may be formed alternately in the first direction D1. A length HMP_W of each of the peripheral mask regions HMP in the second direction D2 may be greater than a length HMC_W of each of the cell mask regions HMC in the second direction D2.

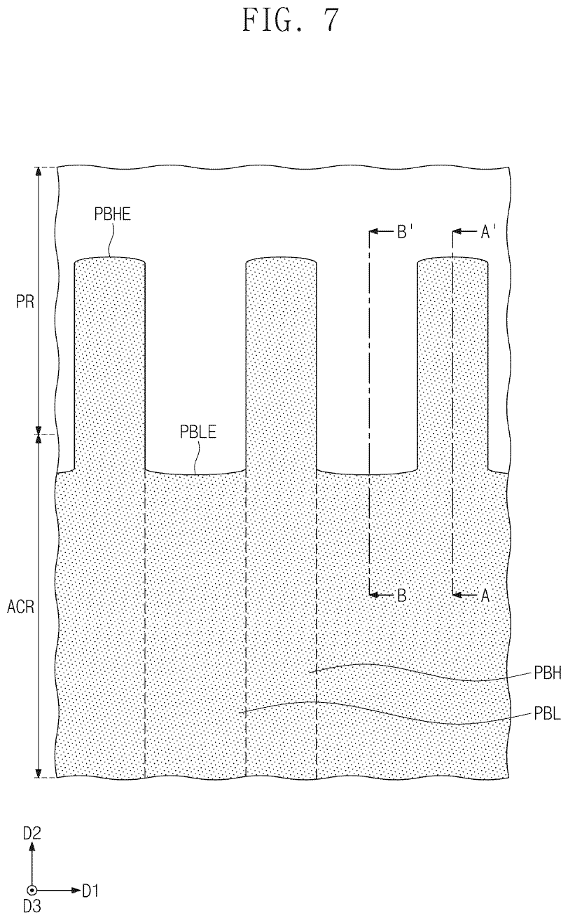

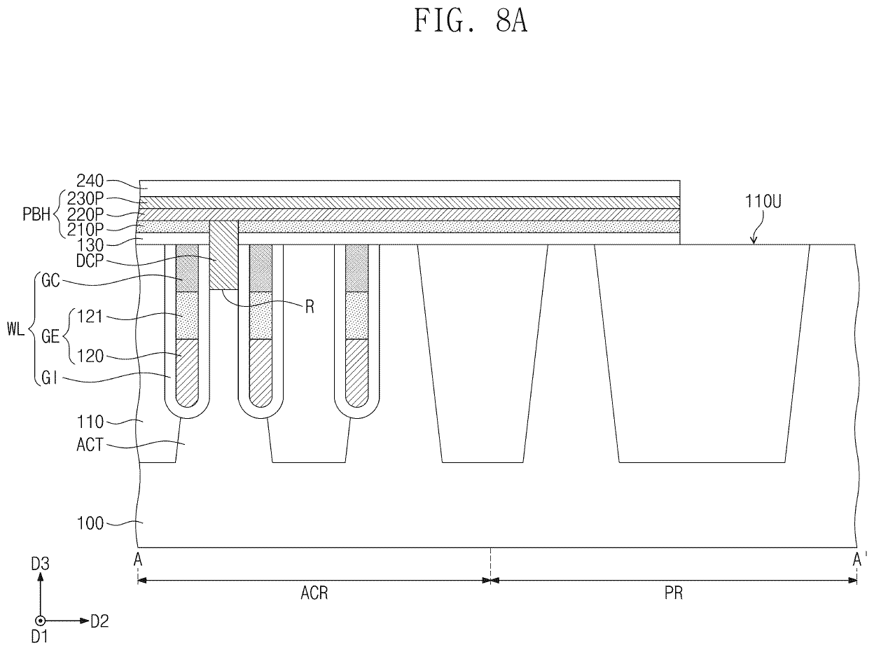

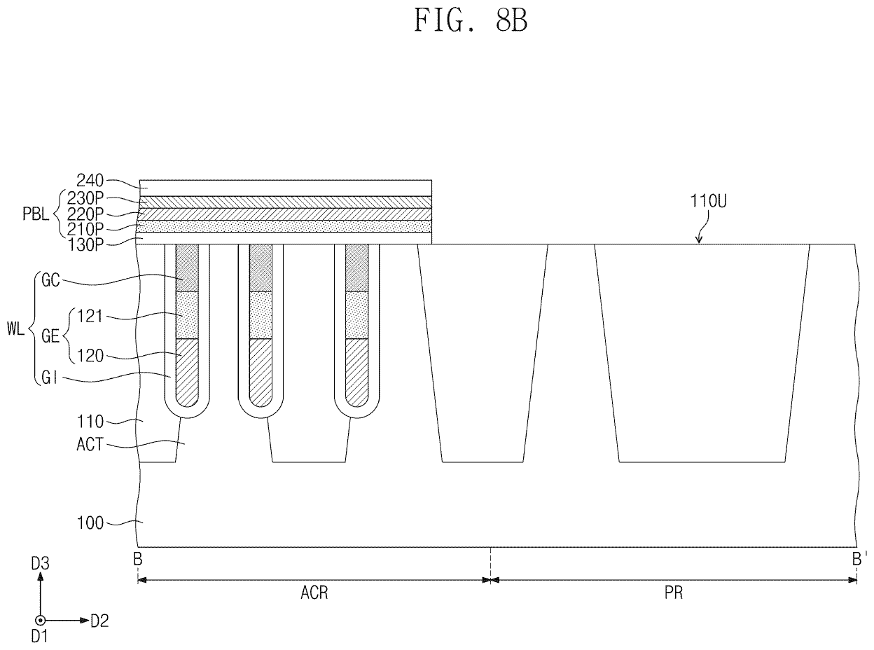

Referring to FIGS. 7 to 8B, using the first bit line mask pattern HM1 as an etch mask, the insulating layer 130, the polysilicon layer 210P, the ohmic layer 220P, the metal-containing layer 230P, and the lower insulating layer 240 may be etched. Due to the cell mask regions HMC, preliminary bit line layers PBL may be formed on the cell region ACR. Due to the peripheral mask pattern HMP, preliminary hammer patterns PBH may be formed on the cell region ACR and the peripheral region PR. The preliminary hammer patterns PBH may extend in the second direction D2. Due to the etching process, each end PBHE of the preliminary hammer patterns PBH may have a curved shape when viewed in a plan view. The preliminary hammer patterns PBH may be spaced apart from each other in the first direction D1. The preliminary bit line layers PBL and the preliminary hammer patterns PBH may be formed alternately in the first direction D1.

Furthermore, due to the etching process, an upper surface 110U of the device isolation layer on the cell region ACR and the peripheral region PR may be exposed. Due to the etching process, each end PBHE of the preliminary hammer patterns PBH may be exposed, and each end PBLE of the preliminary bit line layers PBL may be exposed. The preliminary bit line layers PBL and the preliminary hammer patterns PBH may be formed simultaneously, and after forming the preliminary bit line layers PBL and the preliminary hammer patterns PBH, the first bit line mask pattern HM1 may be removed.

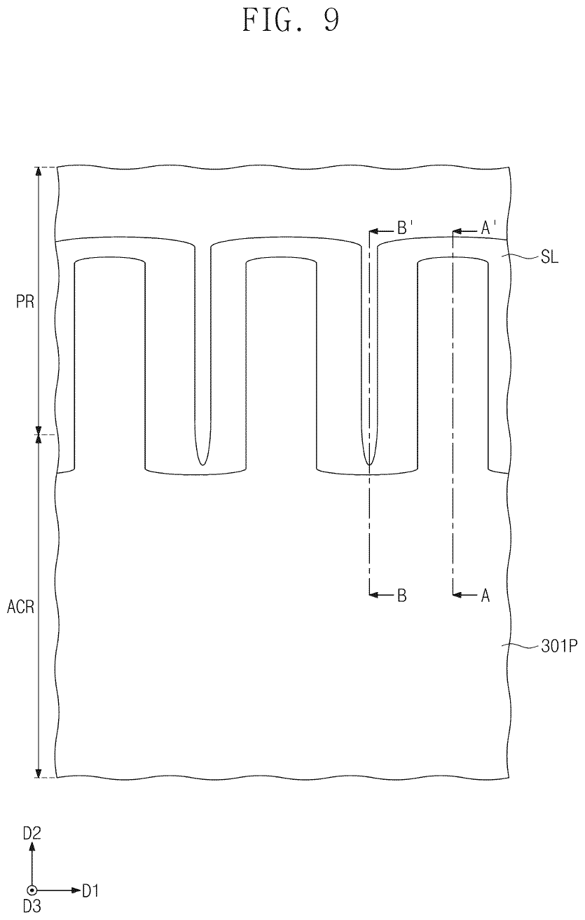

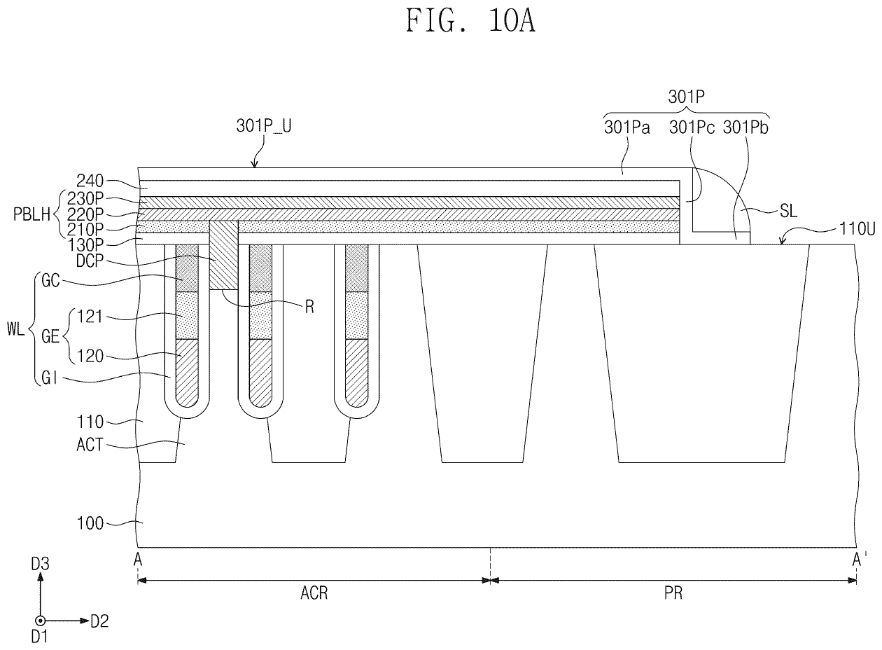

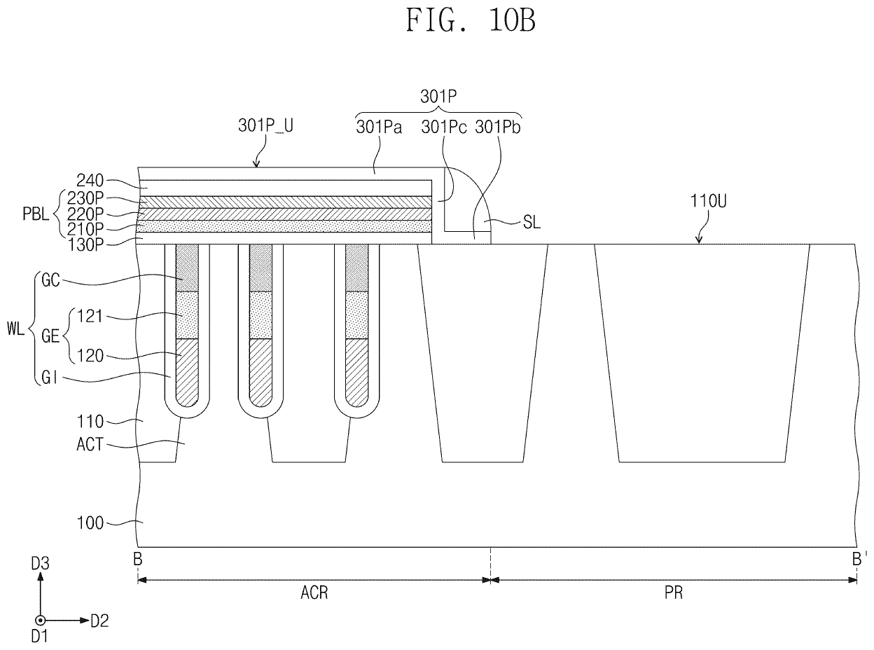

Referring to FIGS. 9 to 10B, a first capping layer 301P may be formed on the preliminary bit line layer PBL and the preliminary hammer patterns PBH. The first capping layer 301P may include a first upper capping layer 301Pa, a first lower capping layer 301Pb, and a first connection capping layer 301Pc connecting the first upper capping layer 301Pa and the first lower capping layer 301Pb.

The first upper capping layer 301Pa may cover an upper surface of the lower insulating layer 240, and the first lower capping layer 301Pb may cover the exposed upper surface 110U of the device isolation layer 110. The first upper capping layer 301Pa and the first lower capping layer 301Pb may have a step in a third direction D3 perpendicular to the upper surface of the substrate 100. The first connection capping layer 301Pc may extend vertically in the third direction D3 to connect the first upper capping layer 301Pa and the first connection capping layer 301Pc.

The first connection capping layer 301Pc may cover each exposed end PBLE of the preliminary bit line layers PBL and each exposed end PBHE of the exposed preliminary hammer patterns PBH.

A spacer layer SL may be formed on the first lower capping layer 301Pb. The spacer layer SL may surround each end PBLE of the preliminary bit line layers PBL and each end PBHE of the preliminary hammer patterns PBH. The spacer layer SL may partially fill a space between the preliminary hammer patterns PBH and partially fill a space between the preliminary hammer patterns PBH and the preliminary bit line layers PBL. For example, forming the spacer layer SL may include filling a preliminary spacer layer and etching the preliminary spacer layer. For example, the etching process may be anisotropic etching.

Due to the etching process, the upper surface 110U of the device isolation layer 110 on the peripheral region PR may be exposed, and the spacer layer SL surrounding the preliminary hammer patterns PBH may be exposed. Furthermore, the spacer layer SL surrounding the preliminary bit line layer PBL may be exposed due to the etching process.

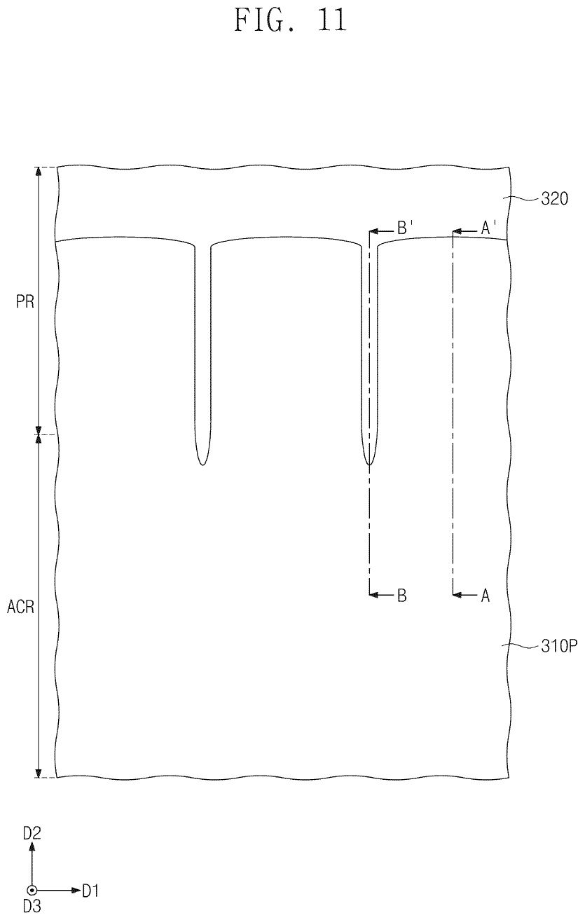

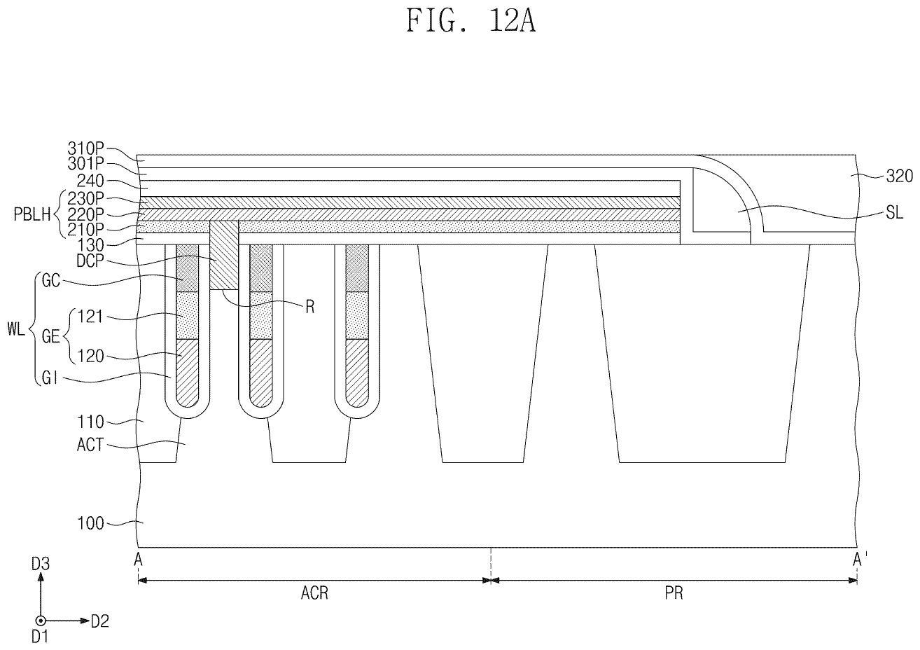

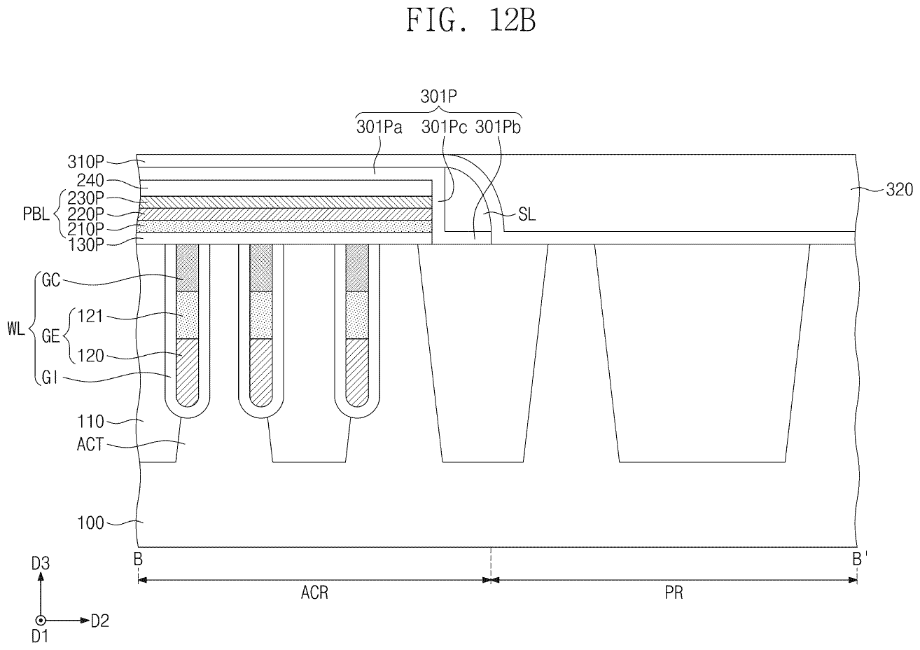

Referring to FIGS. 11 to 12B, a second capping layer 310P may be formed on the cell region ACR and the peripheral region PR. The second capping layer 310P may cover the exposed upper surface 110U of the spacer layer SL and the device isolation layer. That is, the second capping layer 310P may cover the spacer layer SL surrounding the preliminary hammer patterns PBLH and the spacer layer SL surrounding the preliminary bit line layer PBL.

A peripheral insulating layer 320 may be formed on the peripheral region PR. For example, forming the peripheral insulating layer 320 may include forming a preliminary peripheral insulating layer on the second capping layer 310P, and planarizing the preliminary peripheral insulating layer until an upper surface 310P_U of the second capping layer is exposed.

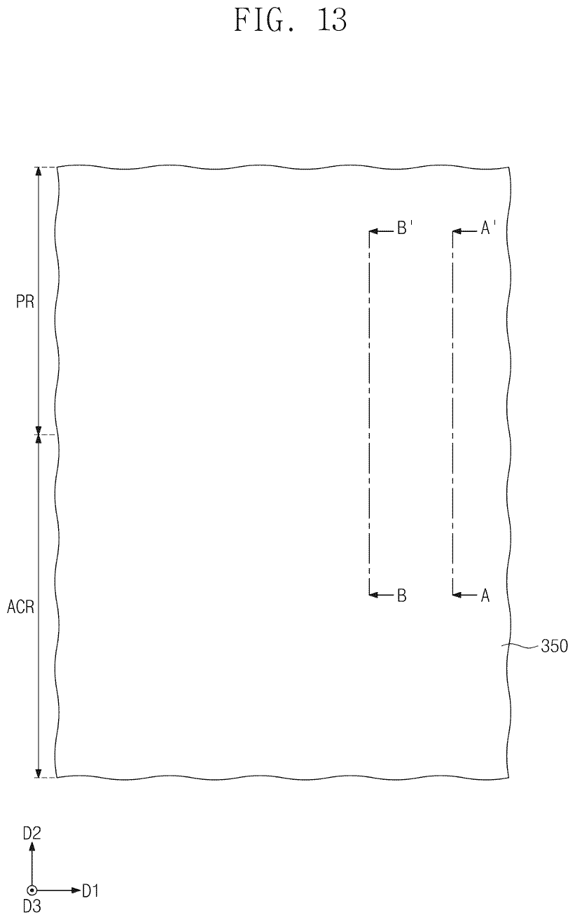

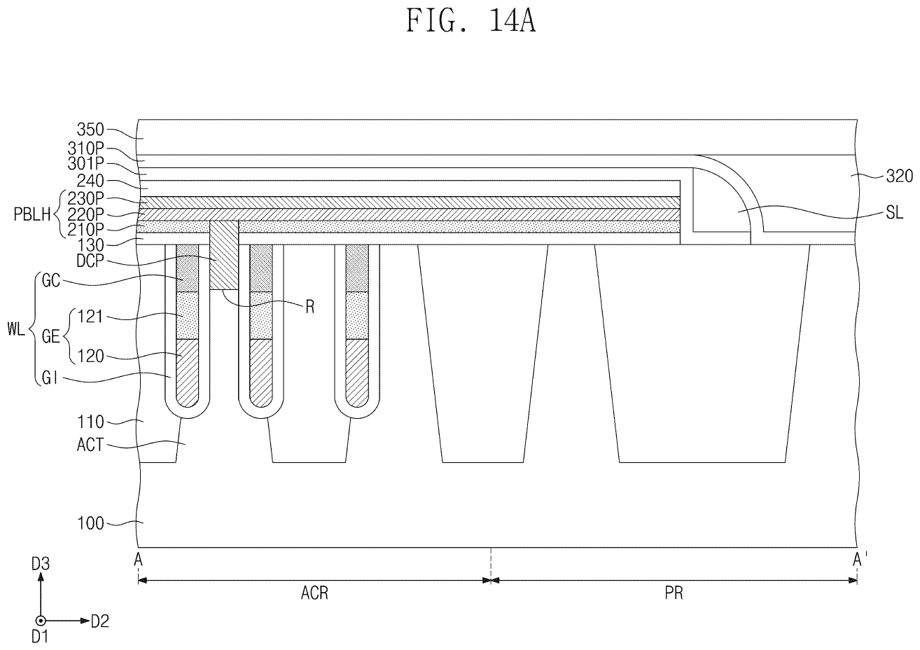

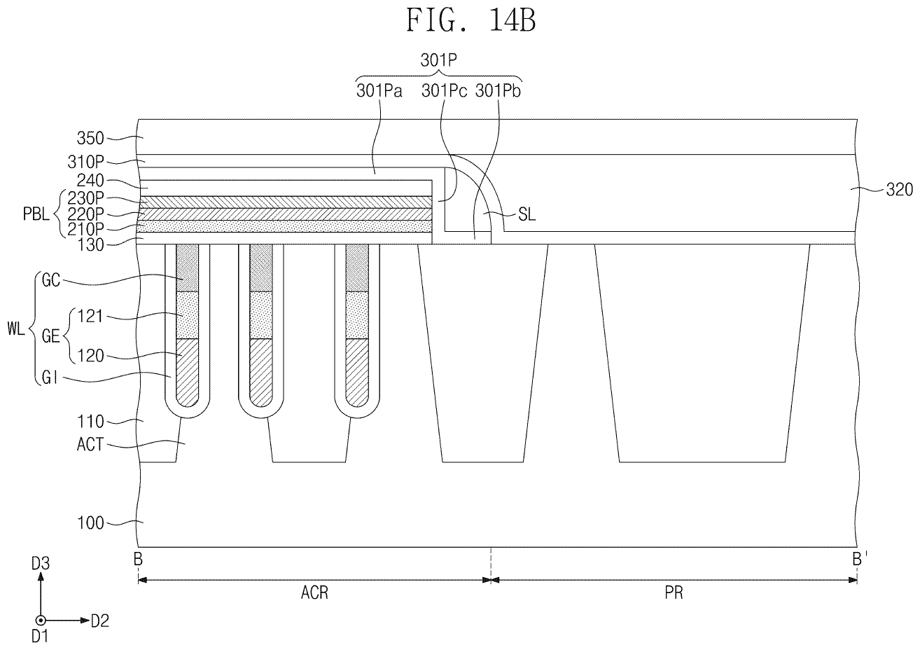

Referring to FIGS. 13 to 14B, a sacrificial layer 350 may be formed on the cell region ACR and the peripheral region PR. The sacrificial layer 350 may be formed on the second capping layer 310P and the peripheral insulating layer 320.

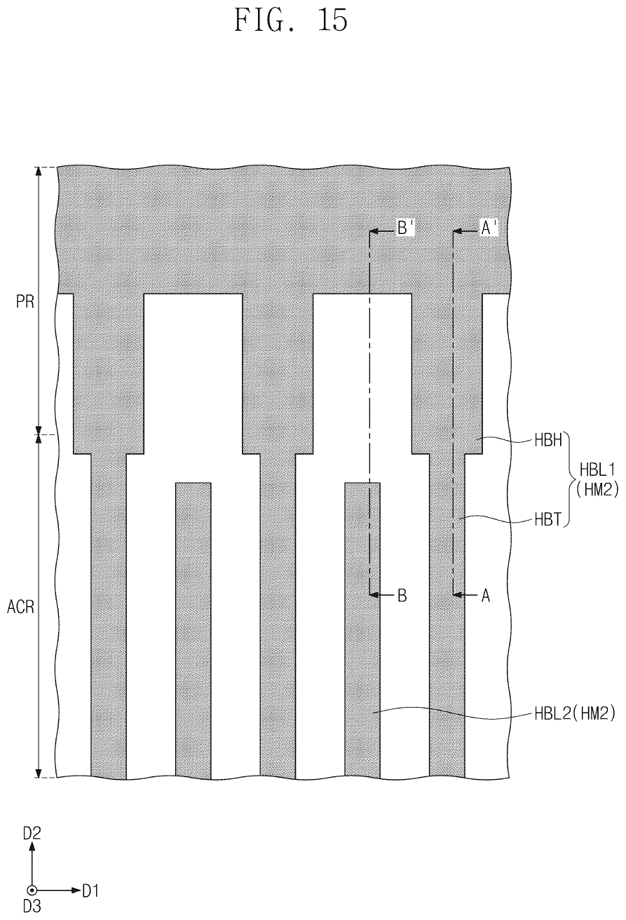

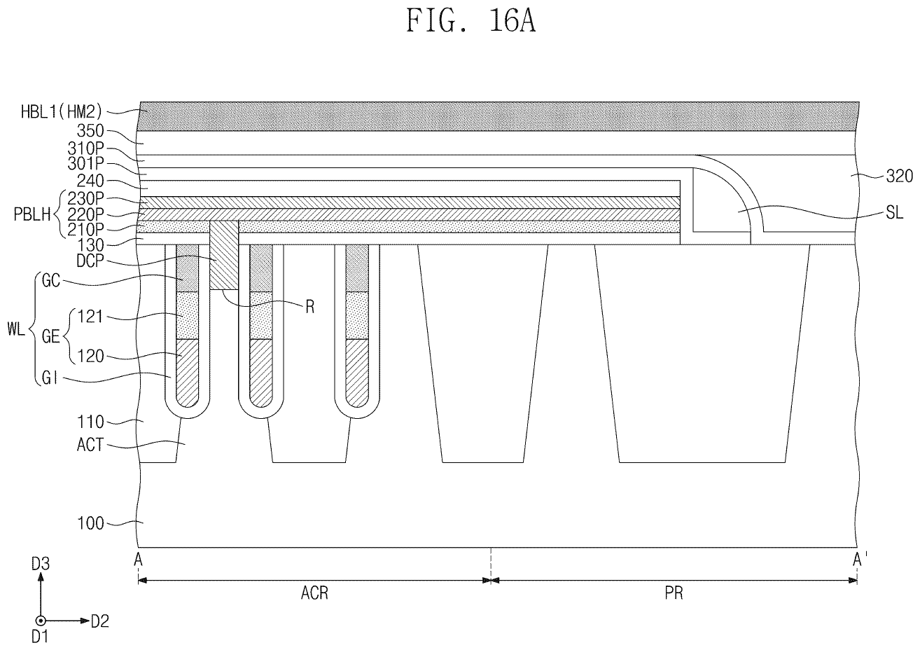

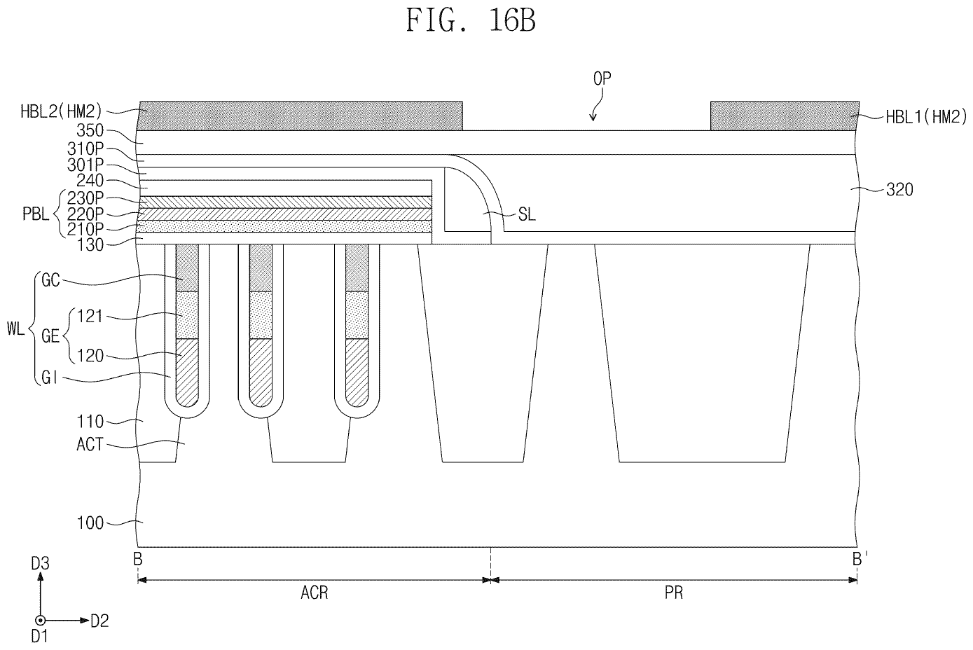

Referring to FIGS. 15 to 16B, a second bit line mask pattern HM2 may be formed on the sacrificial layer 350. The second bit line mask pattern HM2 may include a first mask pattern HBL1 defining a region where the first bit line is formed, and a second mask pattern HBL2 defining a region where the second bit line is formed. For example, the second bit line mask pattern may be a photoresist pattern.

The first mask pattern HBL1 may be formed on the preliminary hammer patterns PBLH. The first mask pattern HBL1 may be formed on the second capping layer 310P on the preliminary hammer patterns PBLH and on the spacer layer SL. The first mask pattern HBL1 may include a tail mask pattern HBT that defines a region where the bit line tail portion is formed, and a hammer mask pattern HBH that defines a region where the bit line hammer portion is formed.

The second mask pattern HBL2 may be formed on the preliminary bit line layers PBL. The second mask pattern HBL2 may be offset from the hammer mask pattern HBH in the second direction D2.

The second bit line mask pattern HM2 may include an opening OP. The opening OP may mean a space between the first mask pattern HM1 and the second mask pattern HM2 in the second direction D2. The opening OP may expose the sacrificial layer 350 on the first capping layer 301P, the spacer layer SL, and the second capping layer 310P surrounding the end of the preliminary bit line pattern PBL.

Referring again to FIGS. 1 to 4, bit lines BL may be formed on the substrate 100. The bit lines may include first bit lines BL1 and second bit lines BL2, and the first bit lines BL1 and the second bit lines BL2 may be spaced apart in the first direction D1.

Each of the first bit lines BL1 may include a bit line tail portion BLT extending in the second direction D2 and a bit line hammer portion BLH connected to an end BLTE of the bit line tail portion BLT. For example, forming the first bit lines BL1 may include etching the preliminary hammer pattern PBLH using the first mask pattern HBL1 as an etch mask. More specifically, the bit line tail portion BLT may be formed using the tail mask pattern HBT as an etch mask, and the bit line hammer portion BLH may be formed using the hammer mask pattern HBH as an etch mask.

For example, forming the second bit lines BL2 may include etching the preliminary bit line pattern PBL using the second mask pattern HBL2 as an etch mask. Each of the second bit lines BL2 may be offset from the bit line hammer portion BLH in the second direction D2. As a result, a bridging phenomenon in which the second bit lines BL2 and the first bit lines BL1 are connected may be reduced or prevented.

The bit lines BL may include a polysilicon pattern 210, an ohmic pattern 220, and a metal-containing pattern 230. Due to the etching process, the polysilicon layer 210P, the ohmic layer 220P, and the metal-containing layer 230P may be etched to form the polysilicon pattern 210, the ohmic pattern 220, and the metal-containing pattern 230.

Through the etching process, the first capping pattern 301 and the second capping pattern 302 may be formed. For example, the first capping layer 301P may be etched using the second bit line mask pattern HM2 as an etch mask to form the first capping pattern 301 and the second capping pattern 302.

Furthermore, a spacer pattern SP and a bit line protection pattern BLP may be formed through the etching process. For example, forming the spacer pattern SP and the bit line protection pattern BLP may include etching the spacer layer SL using the second bit line mask pattern HM2 as an etch mask. In this case, the first mask pattern HBL1 may not be perfectly aligned with the preliminary hammer pattern PBLH. As a result, a width SP1_W of the first portion SP1 of the spacer pattern SP in the first direction D1 and a width SP2_W of the second portion SP2 in the first direction D1 may be different.

Additionally, the third capping pattern 311 and the fourth capping pattern 312 may be formed through the etching process. For example, forming the third capping pattern 311 and the fourth capping pattern 312 may include etching the second capping layer 310P using the second bit line mask pattern HM2 as an etch mask. Due to the loading of the etching process, a width 312H of the fourth capping pattern 312 in the second direction D2 may be smaller than a width BLP_H of the bit line protection pattern BLP in the second direction D2, and may be smaller than a width 302H of the second capping pattern 302 in the second direction D2. Additionally, the width BLP_H of the bit line protection pattern BLP in the second direction D2 may be smaller than the width 302H of the second capping pattern 302 in the second direction D2.

The first bit lines BL1, the second bit lines BL2, the first capping pattern 301, the second capping pattern 302, the spacer pattern SP, and the bit line protection pattern BLP may be formed simultaneously. After the first bit lines BL1, the second bit lines BL2, the first capping pattern 301, the second capping pattern 302, the spacer pattern SP, and the bit line protection pattern BLP are formed, the second bit line mask pattern HM2 may be removed.

According to the inventive concepts, the first capping layer 301P, the spacer layer SL, and the second capping layer 310P may surround an end of the preliminary bit line layer PBL, thereby protecting the preliminary bit line layer PBL, in the etching process of forming the second bit lines BL2.

In addition, as the preliminary bit line layer PBL is not in direct contact with the spacer layer SL containing oxide, the preliminary bit line layer SL may be reduced or prevented from being damaged by oxygen-radicals generated when the spacer layer SL is etched.

That is, according to the inventive concepts, the second bit lines BL2 may be formed without being damaged, and thus reliability of the semiconductor device may be improved and a fabricating process with improved yield may be provided.

Bit line contacts DC may be formed below each of the bit lines BL and may be spaced apart from each other in the first direction D1. For example, forming the bit line contacts DC may include etching the bit line contact layer DCP using the second bit line mask pattern HM2 as an etch mask.

Bit line spacers 400 may be formed to extend along a side surface of the bit lines BL. The bit line spacer 400 may surround side surfaces of the spacer pattern SP and the bit line protection pattern BPL.

Storage node contacts BC may be formed between the first bit lines BL1 and the second bit lines BL2. For example, forming the storage node contacts BC may include forming a preliminary contact layer between the first bit lines BL1 and the second bit lines BL2, planarizing the preliminary contact layer until an upper surface of the first capping pattern 301 is exposed, and patterning the preliminary contact layer.

Landing pads LP may be formed on the storage node contacts BC. Forming the landing pads LP may include forming a conductive layer on the cell region and the peripheral region and patterning the conductive layer.

An upper insulating layer 500 may be formed on the cell region ACR and the peripheral region PR. The upper insulating layer 500 may be formed on the first capping pattern 301. The upper insulating layer 500 may fill a space between the landing pads LP.

Although not illustrated, lower electrodes may be formed on the cell region ACR and the landing pads LP, respectively. A dielectric layer may be formed to cover the surfaces of the lower electrodes. An upper electrode may be formed on the cell region ACR and fill a space between the lower electrodes. The lower electrodes, the dielectric layer, and the upper electrode may form a capacitor.

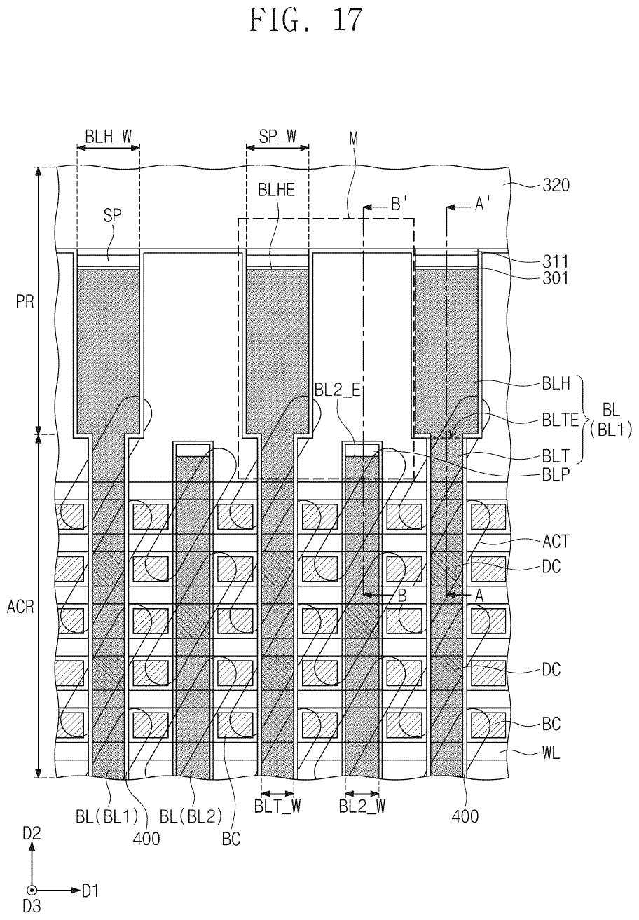

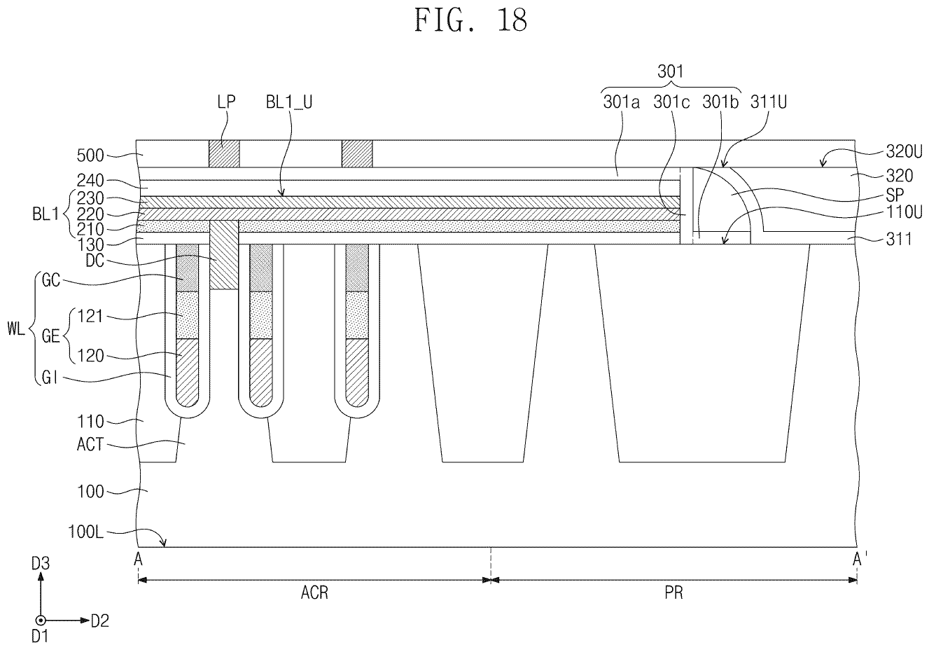

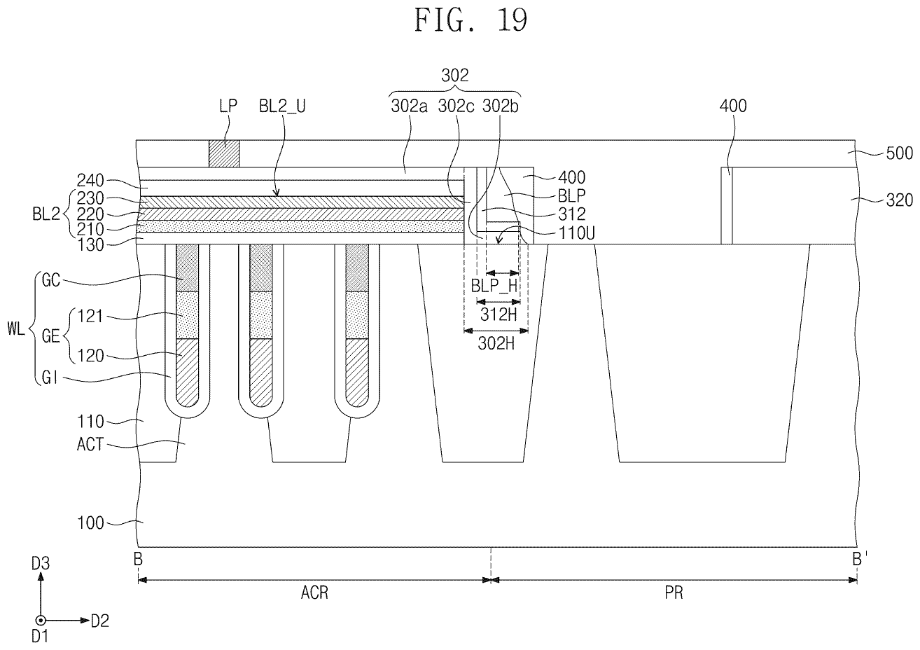

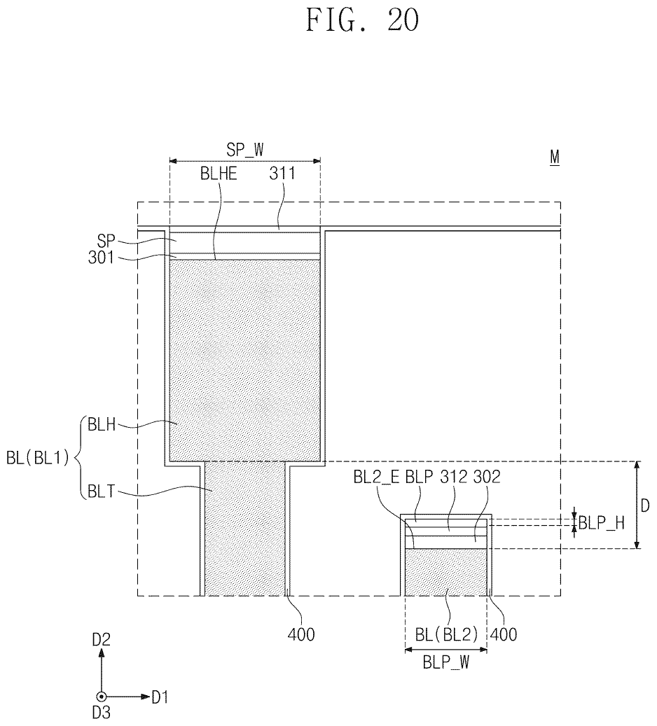

FIG. 17 is a plan view illustrating a semiconductor device according to some example embodiments of the inventive concepts. FIG. 18 is a cross-sectional view taken along line A-A′ of FIG. 17. FIG. 19 is a cross-sectional view taken along line B-B′ of FIG. 17. FIG. 20 is an enlarged view of region ‘M’ in FIG. 17. For simplification, descriptions that overlap with the semiconductor devices described with reference to FIGS. 1 to 4 will be omitted.

Referring to FIGS. 17 to 19, a substrate 100 may be provided. The substrate 100 may be a semiconductor substrate, for example, a silicon substrate, a germanium substrate, or a silicon-germanium substrate. However, example embodiments are not limited thereto. The substrate may include a cell region ACR and a peripheral region PR.

Active patterns ACT may be disposed on the cell region ACR of the substrate 100. A device isolation layer 110 may be disposed on the substrate 100 to define the active patterns ACT. The device isolation layer 110 may be disposed on the cell region ACR and the peripheral region PR of the substrate 100 and may be interposed between the active patterns ACT. For example, the device isolation layer 110 may include silicon oxide, silicon nitride, and/or silicon oxynitride. However, example embodiments are not limited thereto.

Word lines WL may be disposed on the cell region ACR of the substrate 100, and may cross the active patterns ACT and the device isolation layer 110. The word lines WL may extend in the first direction D1 and may be spaced apart in the second direction D2.

An insulating layer 130 may be disposed on the cell region ACR and the peripheral region PR of the substrate 100, and may cover the active patterns ACT, the device isolation layer 110, and the word lines WL. For example, the insulating layer 130 may include a single layer or a multilayer including at least one of a silicon oxide layer, a silicon nitride layer, and a silicon oxynitride layer. However, example embodiments are not limited thereto.

Bit lines BL may be disposed on the cell region ACR and the peripheral region PR of the substrate 100. The bit lines BL may be disposed on the insulating layer 130. The bit lines BL may cross the word lines WL. The bit lines BL may extend in the second direction D2 and may be spaced apart from each other in the first direction D1. The bit lines BL may include first bit lines BL1 and second bit lines BL2 arranged alternately in the first direction D1.

The first bit lines BL1 may include a bit line tail portion BLT extending in the second direction D2 and a bit line hammer portion BLH connected to an end BLTE of the bit line tail portion BLT. The bit line tail portion BLT may be disposed on the cell region ACR, and the bit line hammer portion BLH may be disposed on the peripheral region PR. A width BLH_W of the bit line hammer portion BLH in the first direction D1 may be greater than a width BLT_W of the bit line tail portion BLT in the first direction D1.

The second bit lines BL2 may be disposed on the cell region ACR. Each of the second bit lines BL2 may be offset from the bit line hammer portion BLH in the second direction D2. Furthermore, each of the second bit lines BL2 may be offset from the end BLTE of the bit line tail portion BLT in the second direction D2. A width BL2_W of each of the second bit lines BL2 in the first direction D1 may be smaller than a width BLH_W of the bit line hammer portion BLH in the first direction D1.

A lower insulating layer 240 may be disposed on the bit lines BL. The lower insulating layer 240 may extend in the second direction D2 along an upper surface of the bit lines BL. Among the lower insulating layers 240, the lower insulating layer covering an upper surface BL1_U of the first bit lines BL1 may extend to the cell region ACR and the peripheral region PR. The lower insulating layer 240 covering the upper surfaces BL1_U of the first bit lines BL1 may cover upper surfaces of the bit line tail portion BLT and the bit line hammer portion BLH. Among the lower insulating layers 240, the lower insulating layer 240 covering upper surface BL2_U of the second bit lines BL2 may be disposed on the cell region ACR.

A first capping pattern 301 may be disposed on the lower insulating layer 240 covering the first bit line BL1. The first capping pattern 301 may include a first upper capping pattern 301a, a first lower capping pattern 301b, and a first connection capping pattern 301c connecting the first upper capping pattern 301a and the first lower capping pattern 301b. The first upper capping pattern 301a may be disposed on the lower insulating layer 240, and may be disposed on the cell region ACR and the peripheral region PR. The first lower capping pattern 301b may be disposed on an upper surface of the device isolation layer 110 and may be disposed on the peripheral region PR. The first upper capping pattern 301a and the first lower capping pattern 301b may have a step in a third direction D3 perpendicular to the upper surface of the substrate 100. The first connection capping pattern 301c may extend vertically in the third direction D3 to connect the first upper capping pattern 301a and the first lower capping pattern 301b, and may surround the bit line hammer portion BLH. The first capping pattern 301 (e.g., the first connection capping pattern) may surround (or cover) an end BLHE of the bit line hammer portion BLH. For example, the first capping pattern 301 may be silicon nitride.

A second capping pattern 302 may be disposed on the lower insulating layer 240 covering the second bit lines BL2. The second capping pattern 302 may include a second upper capping pattern 302a, a second lower capping pattern 302b, and a second connection capping pattern 302c connecting the second upper capping pattern 302a and the second lower capping pattern 302b. The second upper capping pattern 302a may be disposed on the lower insulating layer 240 and may be disposed on the cell region ACR. The second lower capping pattern 302b may be disposed on the device isolation layer 110 and may be disposed on the cell region ACR. The second upper capping pattern 302a and the second lower capping pattern 302b may have a step in the third direction D3. The second connection capping pattern 302c may extend vertically in the third direction D3 to connect the second upper capping pattern 302a and the second lower capping pattern 302b, and may surround (or cover) an end BL2_E of each of the second bit lines BL2. The first capping pattern 301 and the second capping pattern 302 may include the same material. For example, the second capping pattern 302 may be silicon nitride.

A spacer pattern SP may be disposed on the peripheral region PR and may be disposed on the first capping pattern 301 (e.g., the first lower capping pattern 301b). The spacer pattern SP may surround the first connection capping pattern 301c and the end BLHE of the bit line hammer portion BLH. For example, the spacer pattern SP may include silicon oxide. The first capping pattern 301 (e.g., the first connection capping pattern) may be interposed between the end BLHE of the bit line hammer portion BLH and the spacer pattern SP.

A third capping pattern 311 may be disposed on the peripheral region PR and on the spacer pattern SP. The third capping pattern 311 may be in contact with the first lower capping pattern 301b. The spacer pattern SP may be interposed between the first capping pattern 301 and the third capping pattern 311. For example, the third capping pattern 311 may be silicon nitride. The spacer pattern SP may be interposed between the first capping pattern 301 and the third capping pattern 311 on the end BLHE of the bit line hammer portion BLH.

A fourth capping pattern 312 may be disposed on the second capping pattern 302 (e.g., second lower capping pattern) and may be disposed on the cell region ACR. For example, the fourth capping pattern 312 may be silicon nitride. The second capping pattern 302 may be interposed between an end BL2_E of each of the second bit lines BL2 and the fourth capping pattern 312.

Referring to FIG. 17, a bit line protection pattern BLP may be disposed on the fourth capping pattern 312. The bit line protection pattern BLP may cover the second connection capping pattern 302c and each end BL2_E of the second bit lines BL2. The bit line protection pattern BLP may be offset from the bit line hammer portion BLH in the second direction D2.

A width BLP_W of the bit line protection pattern BLP in the first direction D1 may be smaller than the maximum width SP_W of the spacer pattern SP in the first direction D1. The width BLP_H of the bit line protection pattern BLP in the second direction D2 may be smaller than a separation distance D between the end BL2_E of the second bit line and the bit line hammer portion BLH in the second direction D2.

The width BLP_H of the bit line protection pattern BLP in the second direction D2 may be smaller than a width 312H of the fourth capping pattern 312 in the second direction D2, and may be smaller than a width 302H of the second capping pattern 302 in the second direction D2. Additionally, the width 312H of the fourth capping pattern 312 in the second direction D2 may be smaller than the width 302H of the second capping pattern 302 in the second direction D2.

The bit line protection pattern BLP may include the same material as the spacer pattern SP, for example, silicon oxide. The fourth capping pattern 312 may be interposed between the second capping pattern 302 and the bit line protection pattern BLP.

Bit line contacts DC may be disposed below each of the bit lines BL and may be spaced apart from each other in the first direction D1. The bit line contacts DC may be disposed on the cell region ACR. Each of the bit line contacts DC may penetrate the insulating layer 130 and the polysilicon pattern 210, and may be electrically connected to each of the active patterns ACT. An ohmic pattern 220 and a metal-containing pattern 230 may cover upper surfaces of the bit line contacts DC. The bit line contacts DC may include one of a doped semiconductor material (e.g., doped silicon, doped germanium, etc.), conductive metal nitride (e.g., titanium nitride, tantalum nitride, etc.), a metal (e.g., tungsten, titanium, tantalum, etc.), and metal-semiconductor compound (e.g., tungsten silicide, cobalt silicide, titanium silicide, etc.). However, example embodiments are not limited thereto.

A bit line spacer 400 may be disposed on each side surface of the bit lines BL. The bit line spacer 400 may extend in the second direction D2 along the side surfaces of each of the bit lines BL. The bit line spacer 400 may extend along side surfaces of the bit line tail portion BLT and the bit line hammer portion BLH, and may extend along each side surface of the second bit lines BL2. The bit line spacer 400 may surround the spacer pattern SP and may surround the bit line protection pattern BLP. Referring to FIG. 17, the bit line spacer 400 may surround the side surfaces of the first capping pattern 301, the spacer pattern SP, and the third capping pattern 311 when viewed in a plan view. Additionally, the bit line spacer 400 may surround side surfaces of the second capping pattern 302, the fourth capping pattern 312, and the bit line protection pattern BLP.

Storage node contacts BC may be disposed between a pair of neighboring bit lines BL and may be spaced apart from each other in the first direction D1. The storage node contacts BC may be disposed on the cell region ACR.

A peripheral insulating layer 320 may be disposed on the peripheral region PR and may be in contact with the third capping pattern 311. An upper surface 320U of the peripheral insulating layer 320 may be substantially coplanar with an upper surface 311U of the third capping pattern 311. For example, the peripheral insulating layer 320 may include silicon oxide.

Although not illustrated, a capacitor structure may be disposed on the cell region ACR and on the upper insulating layer 500. The capacitor structure may include a plurality of lower electrodes respectively disposed on the landing pads LP, an upper electrode covering the plurality of lower electrodes, and a dielectric layer between each of the plurality of lower electrodes and the upper electrode. The plurality of lower electrodes may include at least one of an impurity-doped polysilicon, a metal nitride layer such as titanium nitride, and a metal layer such as tungsten, aluminum, and copper. However, example embodiments are not limited thereto. The plurality of upper electrodes may include at least one of a polysilicon layer doped with an impurity, a silicon germanium layer doped with an impurity, a metal nitride layer such as a titanium nitride layer, and a metal layer such as tungsten, aluminum, and copper. For example, the dielectric layer may include at least one of a silicon oxide layer, a silicon nitride layer, a silicon oxynitride layer, and a high dielectric layer (e.g., a hafnium oxide layer). However, example embodiments are not limited thereto.

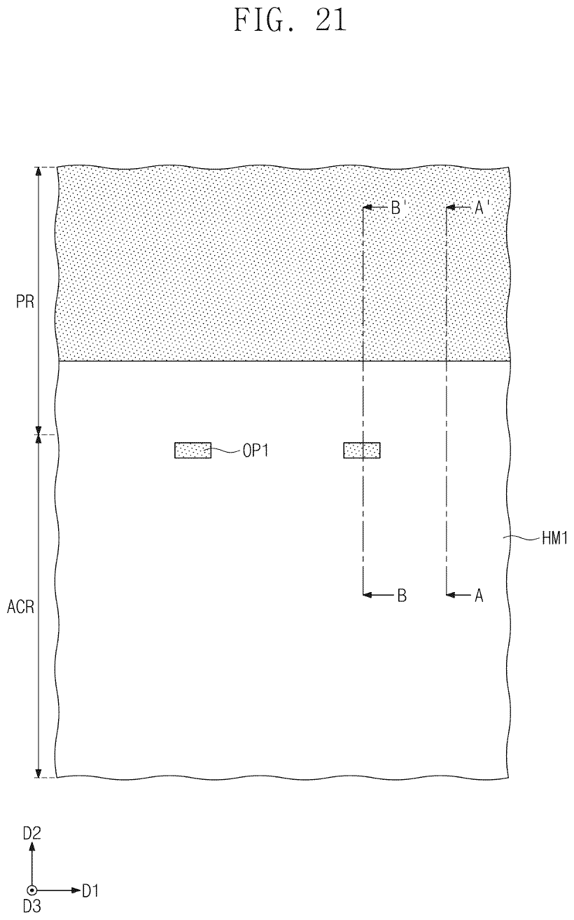

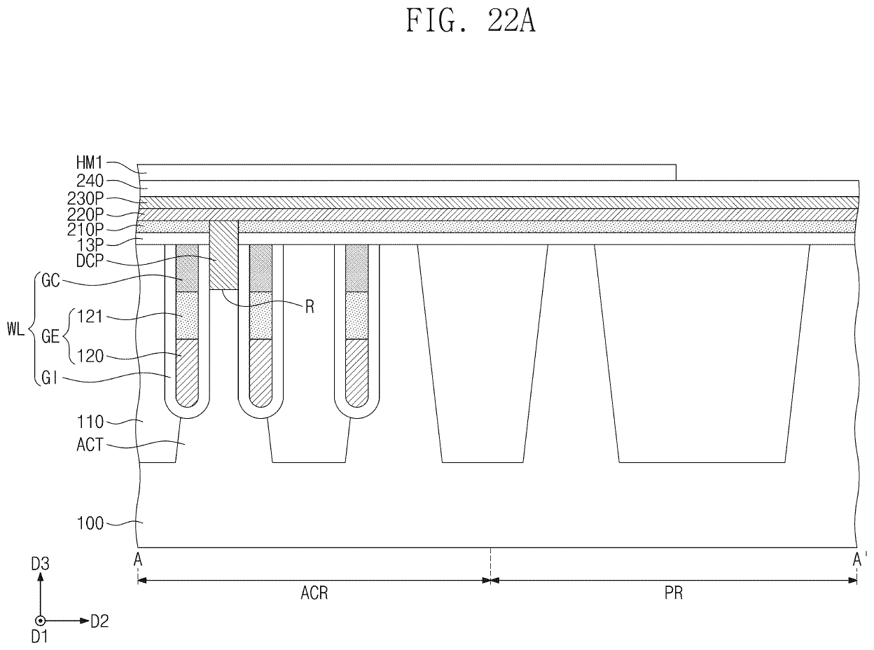

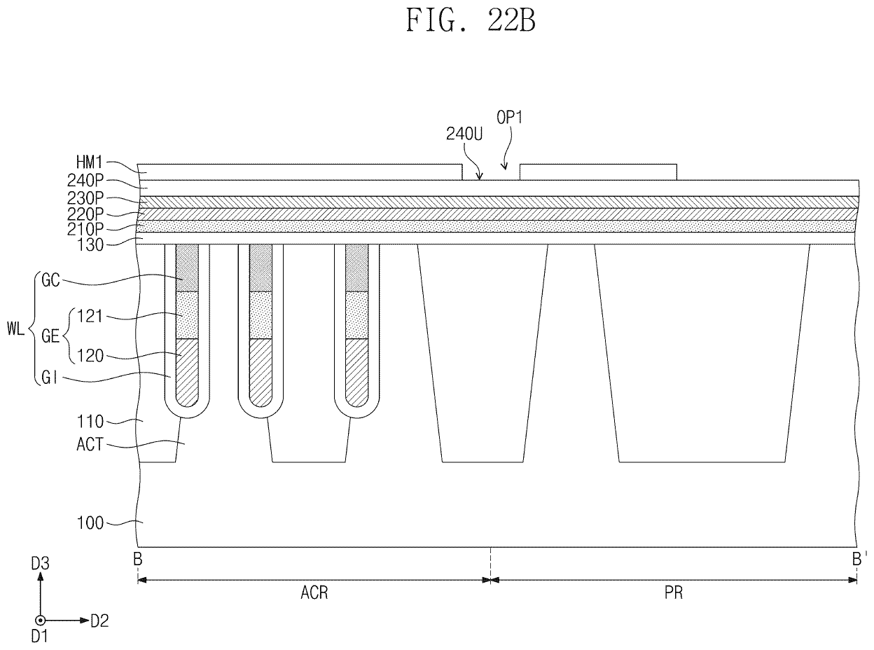

FIGS. 21, 23, 25, 27, 29, 31, 33, and 35 are plan views illustrating a fabricating process of a semiconductor device according to some example embodiments of the inventive concepts. FIGS. 22A, 24A, 26A, 28A, 30A, 32A, 34A, and 36A are cross-sectional views along A-A′ of FIGS. 21, 23, 25, 27, 29, 31, 33, and 35 respectively. FIGS. 22B, 24B, 26B, 28B, 30B, 32B, 34B, and 36B are cross-sectional views along B-B′ of FIGS. 21, 23, 25, 27, 29, 31, 33, and 35 respectively. For simplification, descriptions that overlap with the semiconductor device fabricating method described with reference to FIGS. 5 to 20 will be omitted.

Referring to FIGS. 21 to 22B, an insulating layer 130, a polysilicon layer 210P, an ohmic layer 220P, a metal-containing layer 230P, and a lower insulating layer 240 may be formed on a cell region ACR and a peripheral region PR of a substrate 100.

A first bit line mask pattern HM1 may be formed on the lower insulating layer 240. The first bit line mask pattern HM1 may be formed on the cell region ACR and the peripheral region PR. The first bit line mask pattern HM1 may cover the lower insulating layer 240 on the cell region ACR and a portion of the lower insulating layer 240 on the peripheral region PR. The first bit line mask pattern HM1 may include first openings OP1. The first openings OP1 may be spaced apart from each other in the first direction D1. The first openings OP1 may expose an upper surface 240U of the lower insulating layer 240 on the cell region ACR.

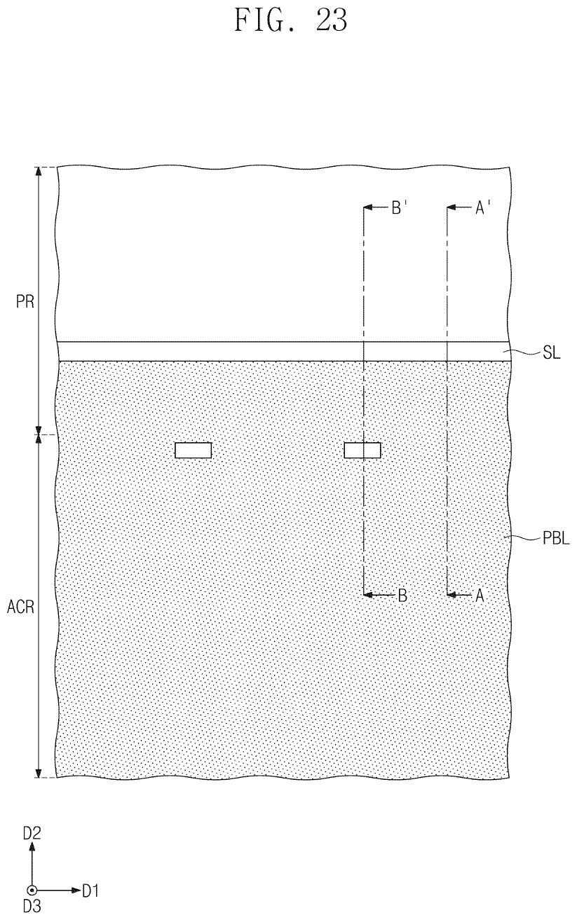

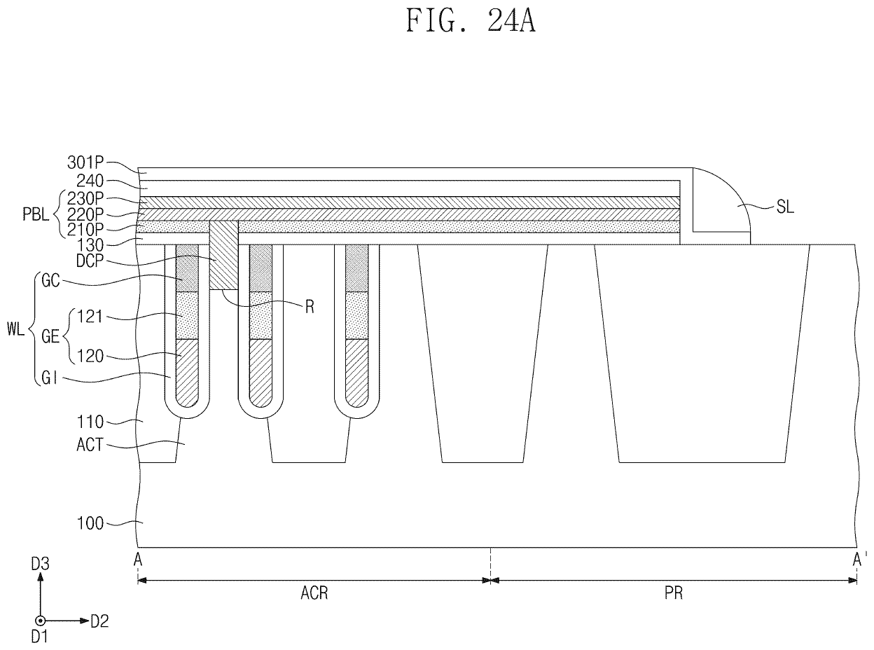

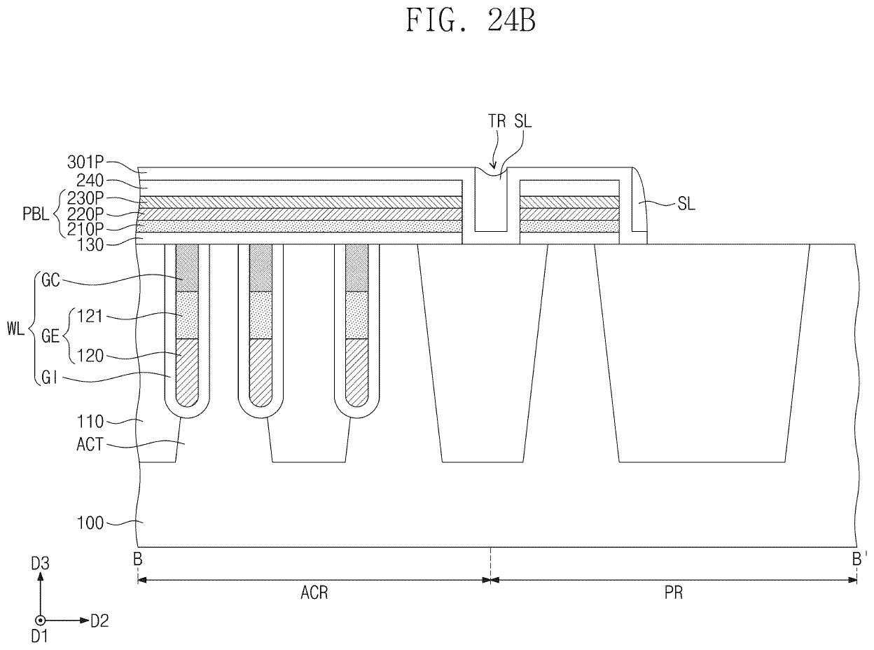

Referring to FIGS. 23 to 24B, a preliminary bit line layer PBL may be formed on the cell region ACR and the peripheral region PR. For example, forming the preliminary bit line layer PBL may include, for example, etching the polysilicon layer 210P, the ohmic layer 220P, the metal-containing layer 230P, and the lower insulating layer 240 by using the first bit line mask pattern HM1 as an etch mask. Due to the etching process, an end of the preliminary bit line layer may be exposed.

The preliminary bit line layer PBL may include trench regions TR. The trench regions TR may be regions formed by the first openings OP1. The trench regions TR may be spaced apart from each other in the first direction D1. Each of the trench regions TR may expose an upper surface 110U of the device isolation layer 110 on the cell region ACR.

A first capping layer 301P may be formed on the lower insulating layer 240. The first capping layer 301P may cover the exposed end of the preliminary bit line layer PBL. The first capping layer 301P may fill the trench regions TR and cover the upper surface 110U of the device isolation layer exposed by the trench regions TR.

A spacer layer SL may be formed on the first capping layer 301P. The spacer layer SL may fill the trench regions TR. For example, forming the spacer layer SL may include depositing a first insulating material on the first capping layer 301P and etching the first insulating material. For example, the etching process may be an anisotropic etching process.

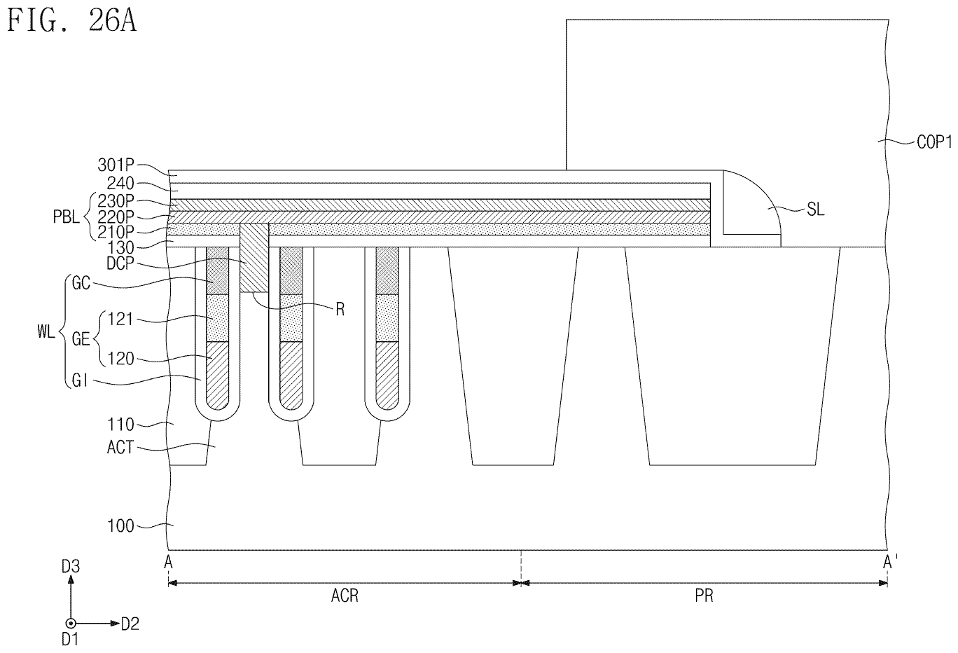

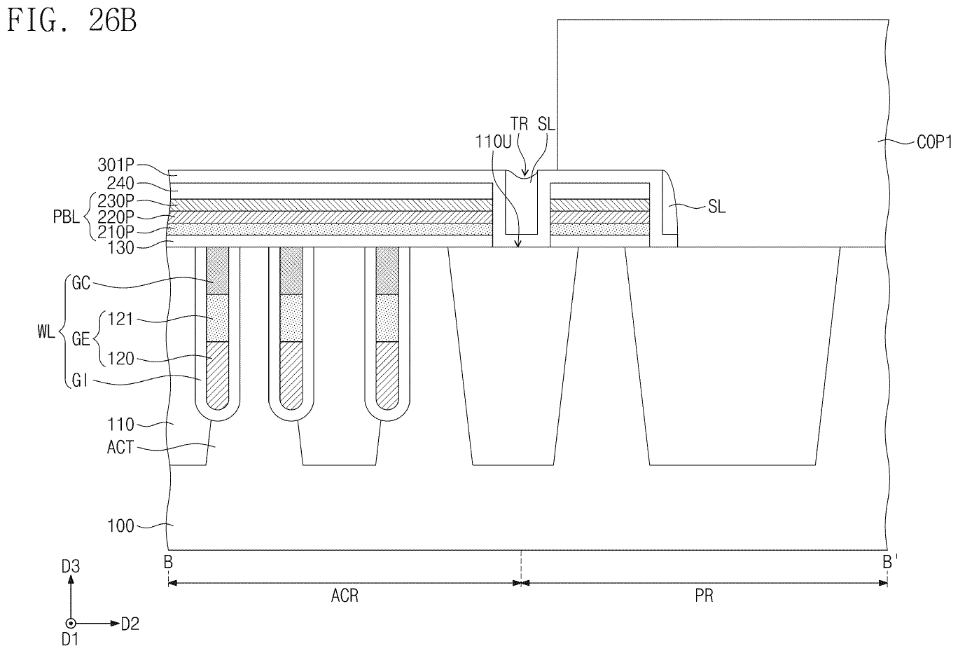

Referring to FIGS. 26 to 26B, a first peripheral mask pattern COP1 may be formed on the peripheral region PR. The first peripheral mask pattern COP1 may be formed on the preliminary bit line layer PBL disposed on the peripheral region PR, and may cover the first capping layer 301P and the spacer layer SL on the peripheral region PR. The first peripheral mask pattern may expose the spacer layer SL filling the trench regions TR.

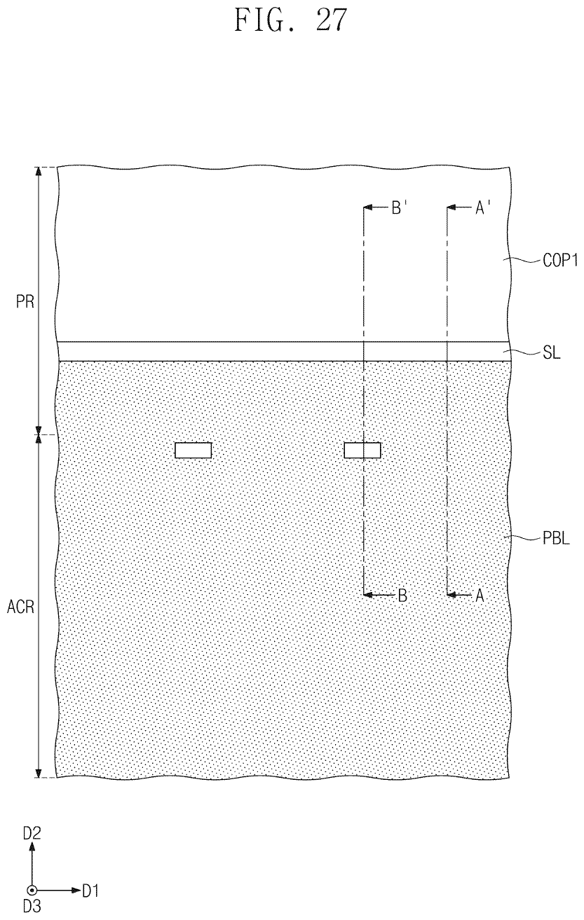

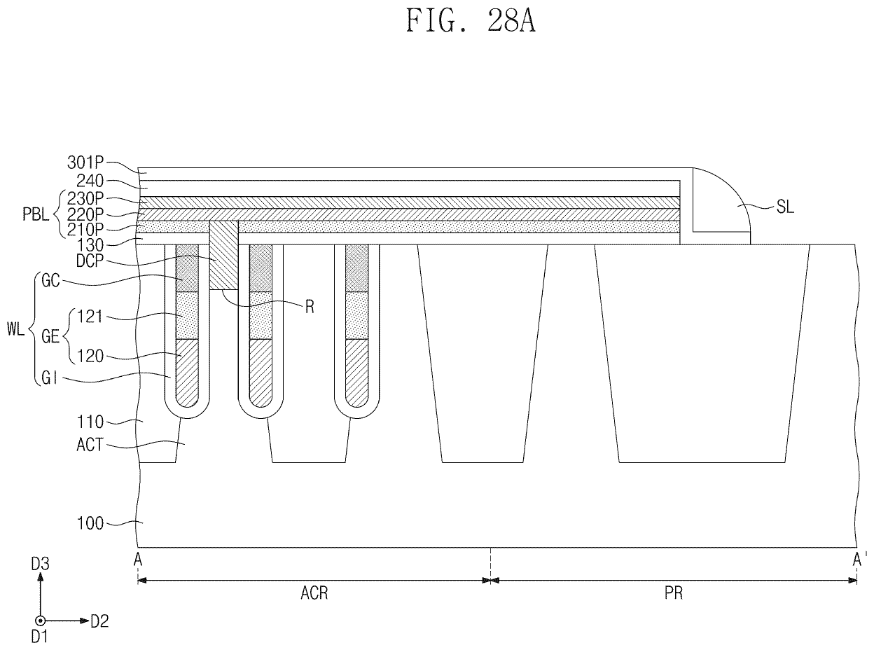

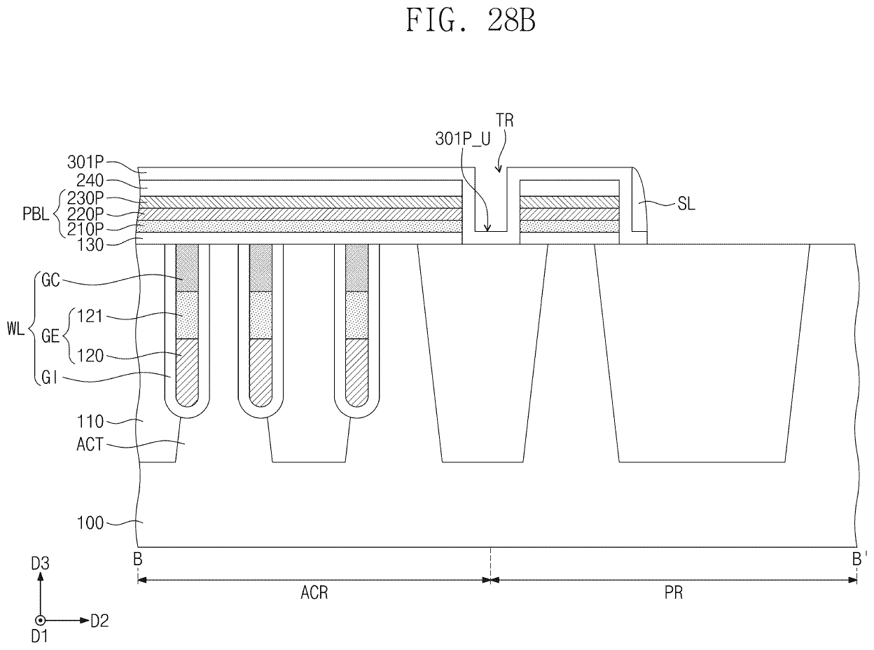

Referring to FIGS. 27 to 28B, the spacer layer SL filling the trench regions TR may be removed. For example, removing the spacer layer SL may include etching the spacer layer SL filling the trench regions TR using the first peripheral mask pattern COP1 as an etch mask. Due to the etching process, an upper surface 301P_U of the first capping layer 301P on the trench regions TR may be exposed. After etching the spacer layer SL filling the trench regions TR, the first peripheral mask pattern COP1 may be removed.

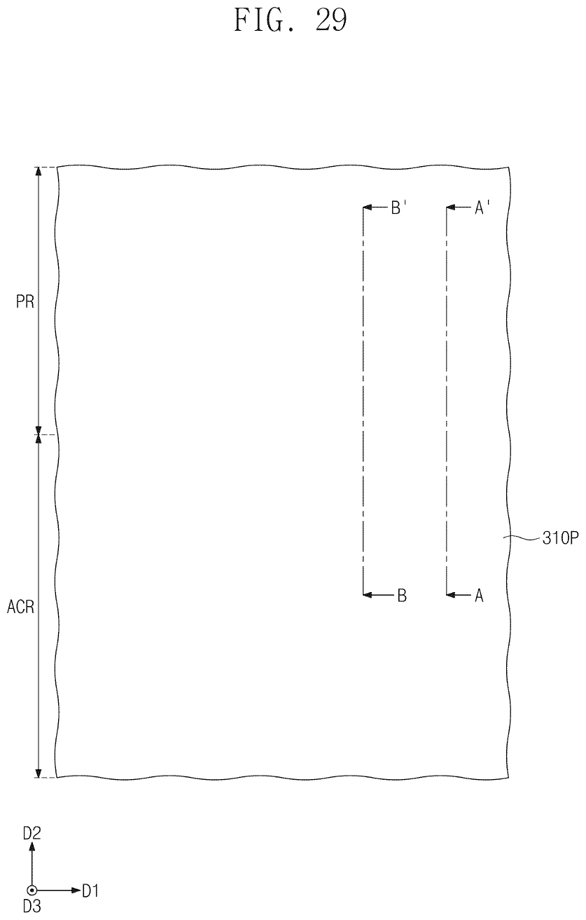

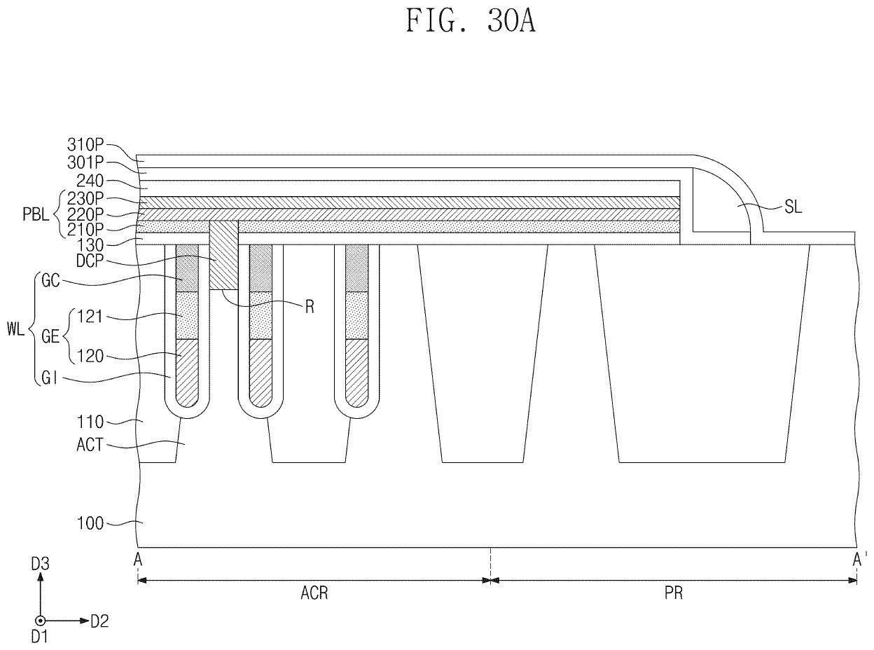

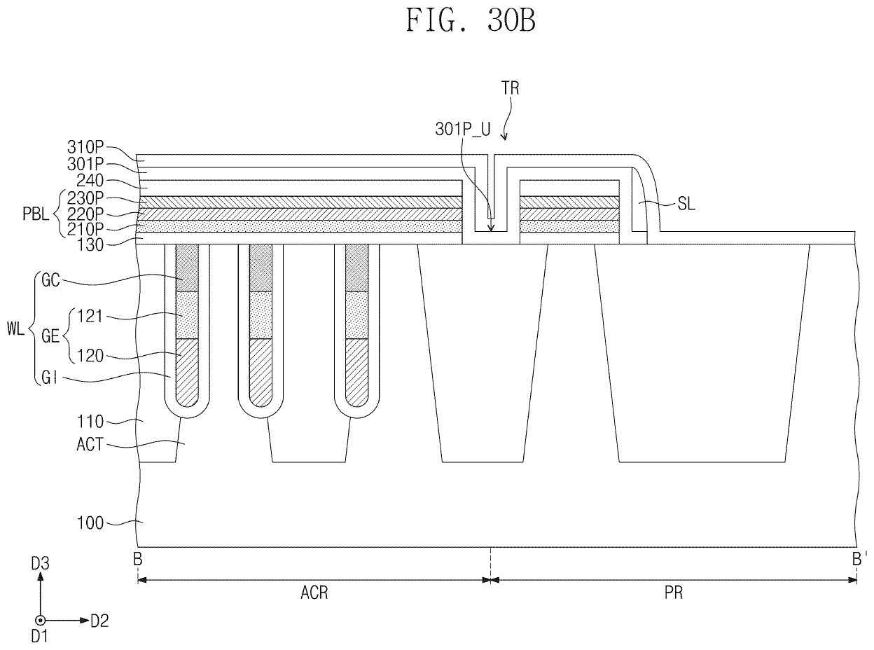

Referring to FIGS. 29 to 30B, a second capping layer 310P may be formed on the first capping layer 301P. The second capping layer 310P may extend onto the cell region ACR and the peripheral region PR. The second capping layer 310P may cover the exposed upper surface 301P_U of the first capping layer 301P.

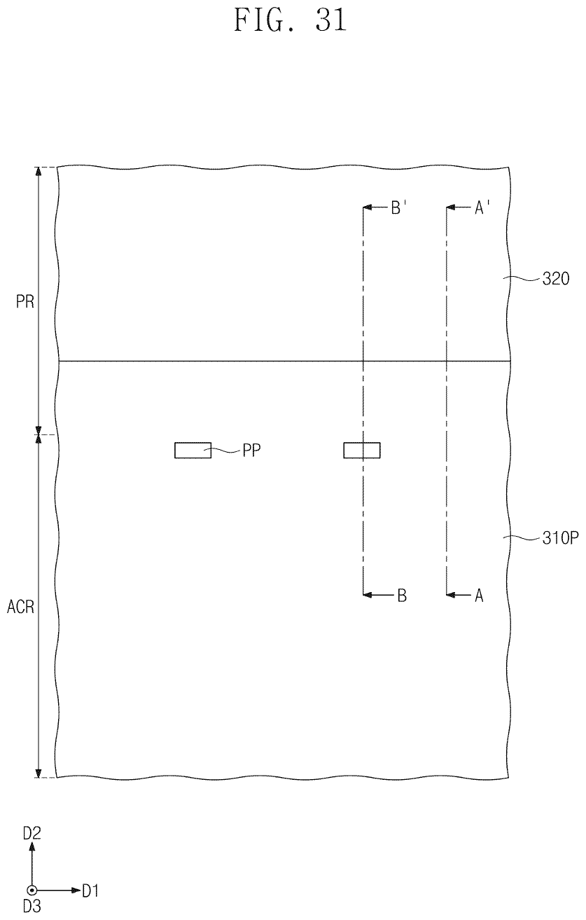

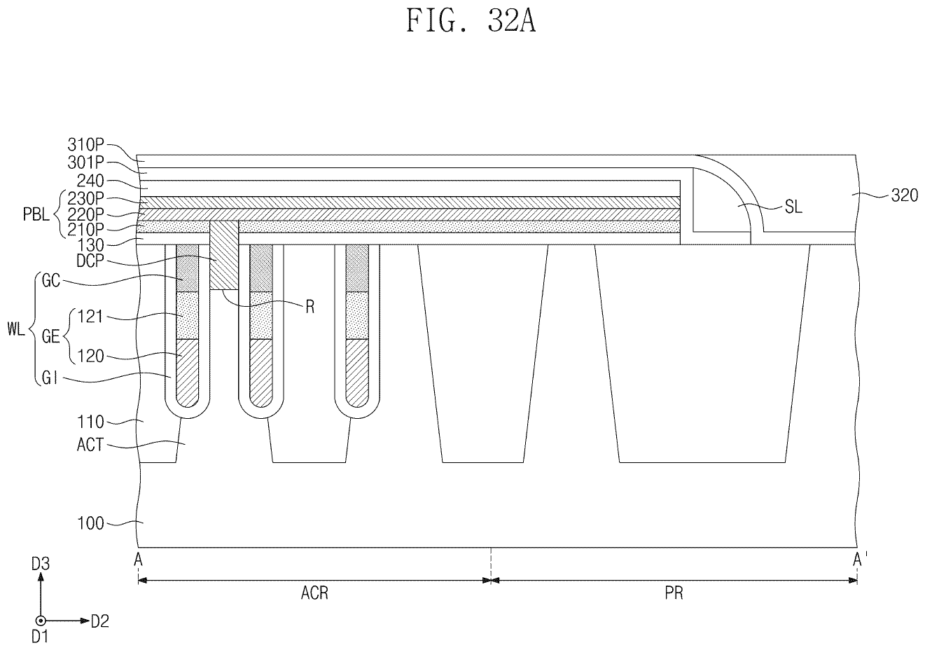

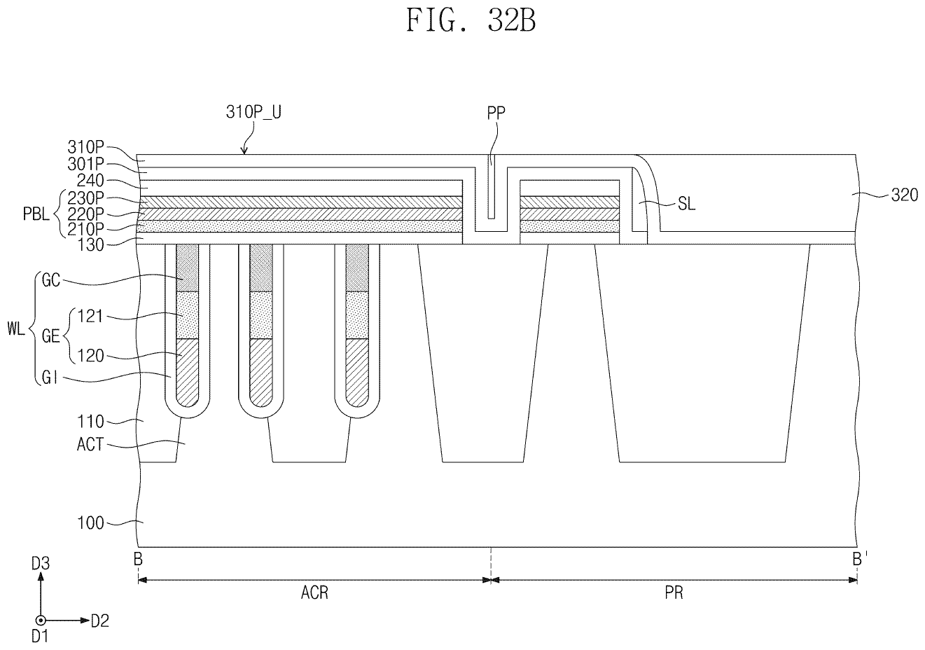

Referring to FIGS. 31 to 32B, a peripheral insulating layer 320 may be formed on the peripheral region PR. For example, forming the peripheral insulating layer 320 may include forming a second insulating material on the cell region ACR and the peripheral region PR and planarizing the second capping layer 310P until the second capping layer 310P is exposed.

The preliminary bit line protection pattern PP may fill the trench regions TR on the cell region ACR. The preliminary bit line protection pattern PP may be formed of the same material as the second insulating material forming the peripheral insulating layer 320. Forming the preliminary bit line protection pattern PP may include, for example, filling the trench regions TR with a second insulating material and planarizing the second insulating material until an upper surface 310P_U of the second capping layer 310P is exposed. The preliminary bit line protection pattern PP and the peripheral insulating layer 320 may be formed simultaneously.

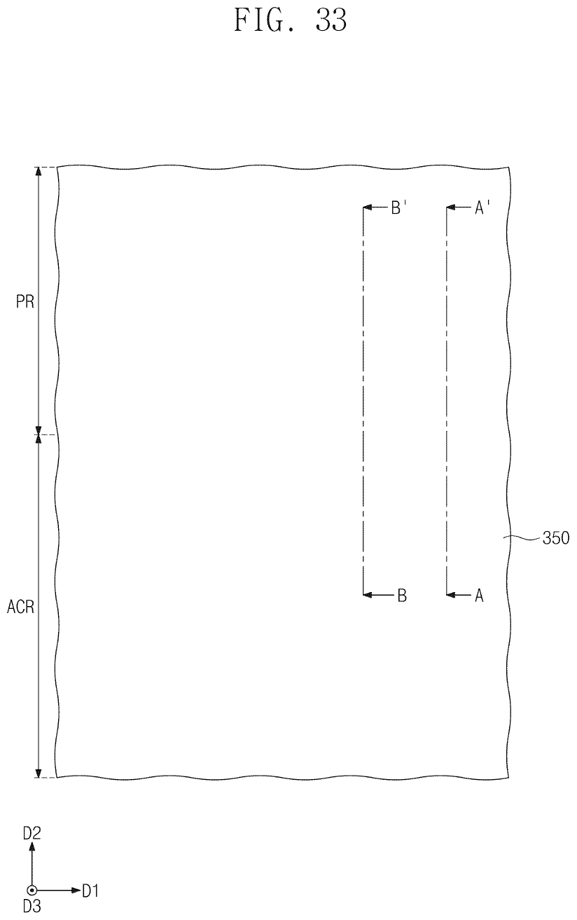

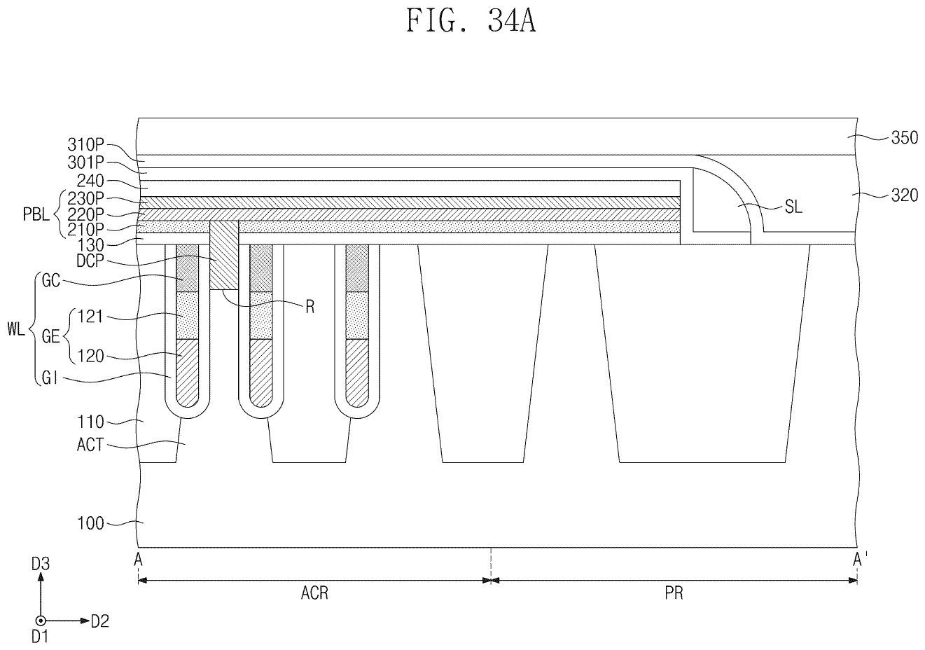

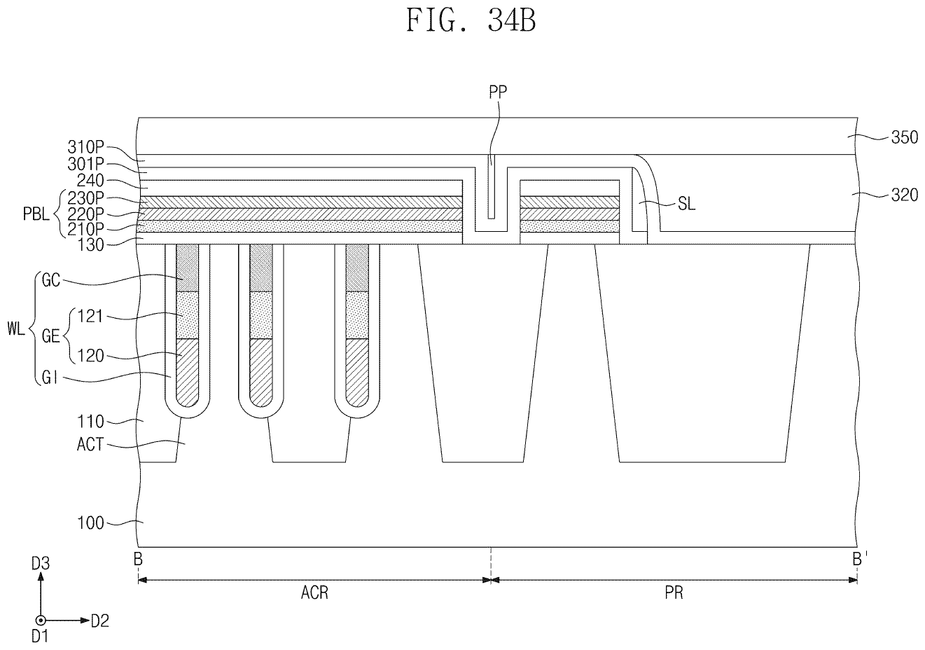

Referring to FIGS. 33 to 34B, a sacrificial layer 350 may be formed on the second capping layer 310P and the peripheral insulating layer 320.

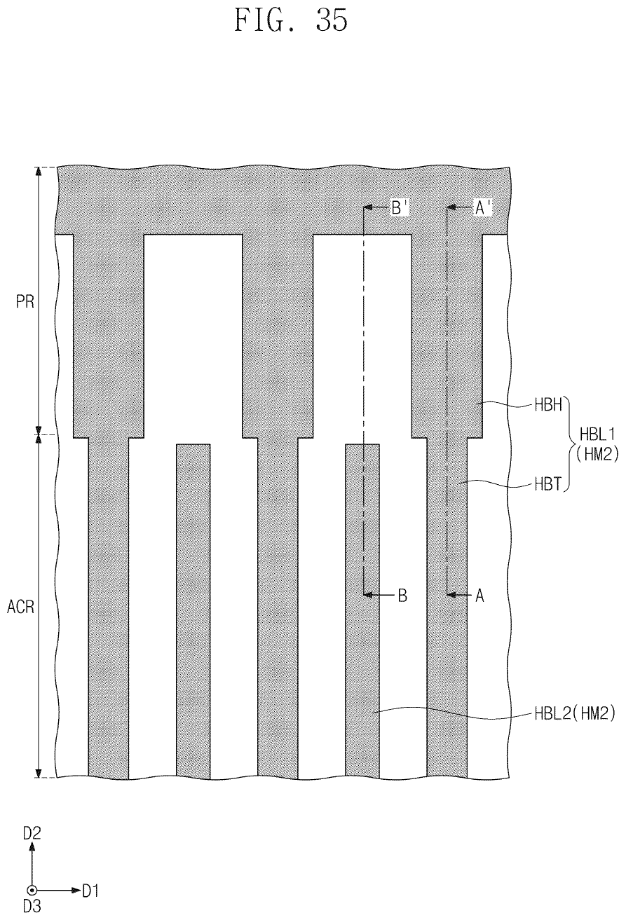

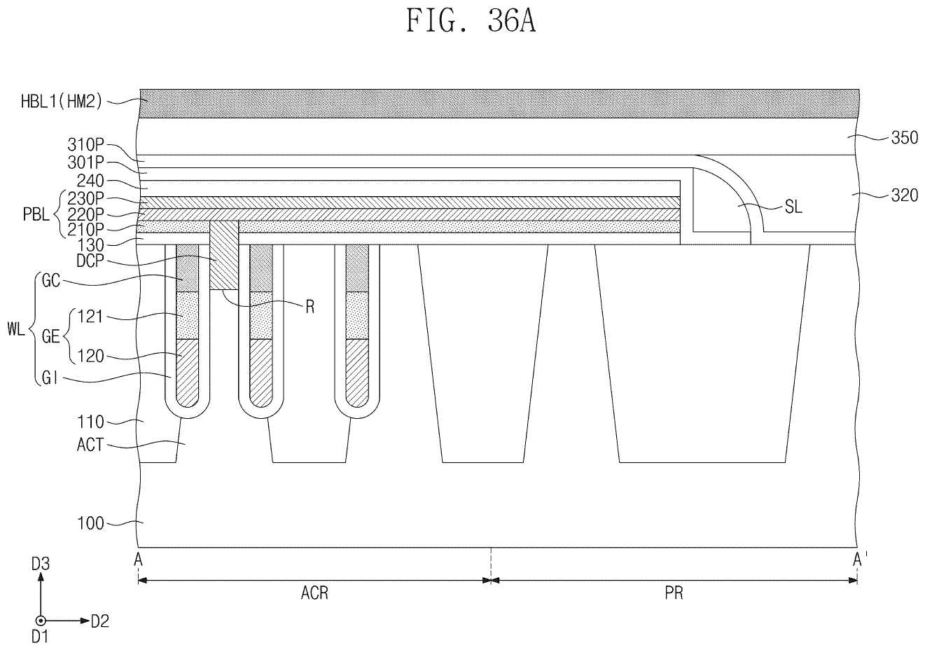

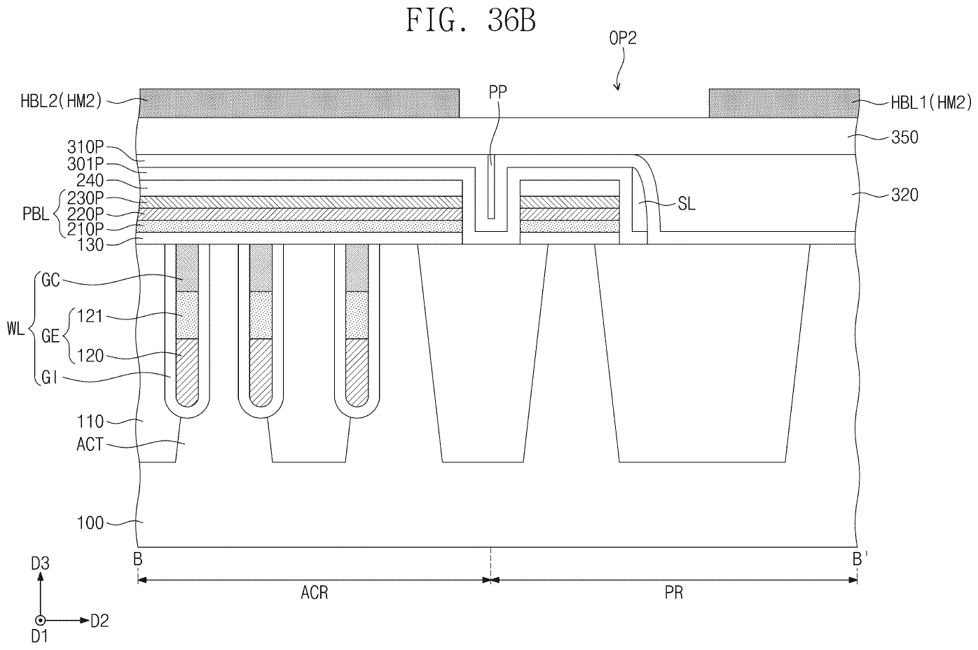

Referring to FIGS. 35 to 36B, a second bit line mask pattern HM2 may be formed on the sacrificial layer 350. The second bit line mask pattern HM2 may include a first mask pattern HBL1 defining a region where the first bit line is formed and a second mask pattern HBL2 defining a region where the second bit line is formed. For example, the second bit line mask pattern HBM2 may be a photoresist pattern.

The first mask pattern HBL1 may include a tail mask pattern HBT that defines a region where the bit line tail portion is formed, and a hammer mask pattern HBH that defines a region where the bit line hammer portion is formed.

The second mask pattern HBL2 may be offset from the hammer mask pattern HBH in the second direction D2. Additionally, the end portion of the second mask pattern HBL2 may be offset from the end portion of the tail mask pattern HBT in the second direction D2.

The second bit line mask pattern HM2 may include a second opening OP2. The second opening OP2 may mean a space between the first mask pattern HBL1 and the second mask pattern HBL2 in the second direction D2. The second opening OP2 may expose the sacrificial layer 350 corresponding to the trench region TR.

Referring again to FIGS. 17 to 20, bit lines BL may be formed on the substrate 100. The bit lines BL may include first bit lines BL1 and second bit lines BL2, and the first bit lines BL1 and the second bit lines BL2 may be spaced apart from each other in the first direction D1.

Each of the first bit lines BL1 may include a bit line tail portion BLT extending in the second direction D2 and a bit line hammer portion BLH connected to an end BLTE of the bit line tail portion BLT. For example, forming the first bit lines BL1 may include etching the preliminary bit line layer PBL using the first mask pattern HBL1 as an etch mask. More specifically, the bit line tail portion BLT may use the tail mask pattern HBT as an etch mask, and the bit line hammer portion BLH may be formed using the hammer mask pattern BLH as an etch mask.

For example, forming the second bit lines BL2 may include etching the preliminary bit line layer PBL using the second mask pattern HBL2 as an etch mask. Each of the second bit lines BL2 may be offset from the bit line hammer portion BLH in the second direction D2. As a result, a short circuit phenomenon in which the second bit lines BL2 and the first bit lines BL1 are connected to each other may be reduced or prevented.

Through the etching process, the first capping pattern 301 and the second capping pattern 302 may be formed. For example, forming the first capping pattern 301 and the second capping pattern 302 may include etching the first capping layer 301P using the second bit line mask pattern HM2 as an etch mask.

Furthermore, a spacer pattern SP and a bit line protection pattern BLP may be formed through the etching process. For example, forming the spacer pattern SP may include etching the spacer layer SL using the second bit line mask pattern HM2 as an etch mask. For example, forming the bit line protection pattern BLP may include etching the preliminary bit line protection pattern PP using the second bit line mask pattern HM2 as an etch mask.

Additionally, a third capping pattern 311 and a fourth capping pattern 312 may be formed through the etching process. For example, forming the third capping pattern 311 and the fourth capping pattern 312 may include etching the second capping layer 310P using the second bit line mask pattern HM2 as an etch mask. Due to loading of the etching process, a width BLP_H of the bit line protection pattern BLP in the second direction D2 may be small than a width 312H of the fourth capping pattern 312 in the second direction D2, and may be smaller than a width 302H of the second capping pattern 302 in the second direction D2. Additionally, the width 312H of the fourth capping pattern 312 in the second direction D2 may be smaller than the width 302H of the second capping pattern 302 in the second direction D2.

According to the inventive concepts, the first capping layer 301P, the spacer layer SL, and the second capping layer may surround the end of the preliminary bit line layer PBL, thereby protecting the preliminary bit line layer PBL, in the etching process of forming the second bit lines BL2.

In addition, as the preliminary bit line layer PBL is not in direct contact with the preliminary bit line protection pattern PP containing oxide, the preliminary bit line layer PBL may be reduced or prevented from being damaged by oxygen-radicals generated when the preliminary bit line protection pattern PP is etched.

That is, according to the inventive concepts, the second bit lines BL2 may be formed without being damaged, and thus reliability of the semiconductor device may be improved and a fabricating process with improved yield may be provided.

Bit line spacers 400 may be formed along side surfaces of the bit lines BL. The bit line spacer 400 may be formed to surround the second capping pattern 302 and the bit line protection pattern BLP.

Storage node contacts BC may be formed between the first bit lines BL1 and the second bit lines BL2. For example, forming the storage node contacts BC may include forming a preliminary contact layer between the first bit lines BL1 and the second bit lines BL2, planarizing the preliminary contact layer until an upper surface of the first capping pattern is exposed, and patterning the preliminary contact layer.

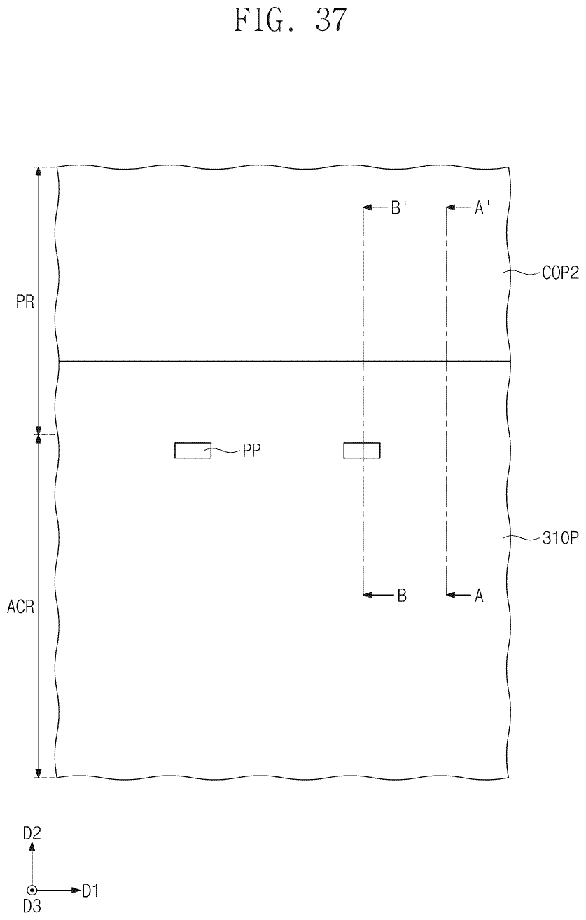

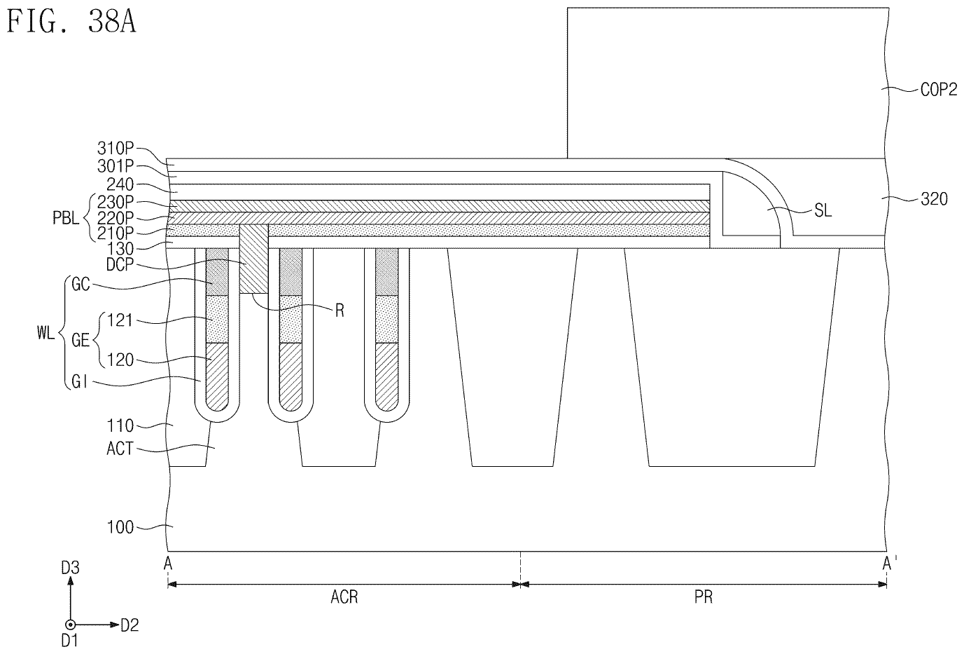

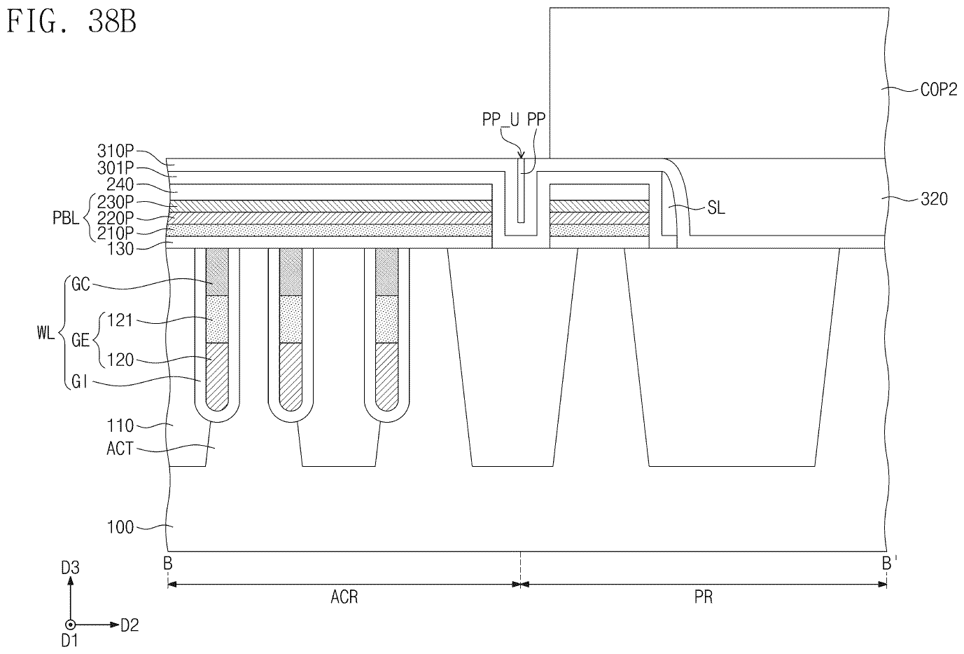

FIGS. 37, 39, 41, and 43 are plan views illustrating a fabricating process of a semiconductor device according to some example embodiments of the inventive concepts, respectively. FIGS. 38A, 40A, 42A, and 44A are cross-sectional views taken along line A-A′ of FIGS. 37, 39, 41, and 43, respectively. FIGS. 38B, 40B, 42B, and 44B are cross-sectional views taken along line B-B′ of FIGS. 37, 39, 41, and 43, respectively. For simplification, descriptions that overlap with the method of fabricating the semiconductor device described with reference to FIGS. 5 to 16B will be omitted.

Referring again to FIGS. 21 to 22B, an insulating layer 130, a polysilicon layer 210P, an ohmic layer 220P, a metal-containing layer 230P, and a lower insulating layer 240 may be formed on a cell region ACR and a peripheral region PR on a substrate 100.

A first bit line mask pattern HM1 may be formed on the lower insulating layer 240. The first bit line mask pattern HM1 may be formed on the cell region ACR and the peripheral region PR. The first bit line mask pattern HM1 may cover the lower insulating layer 240 on the cell region ACR and a portion of the lower insulating layer 240 on the peripheral region PR. The first bit line mask pattern HM1 may include first openings OP1. The first openings OP1 may be spaced apart from each other in the second direction D2. The openings OP may expose an upper surface 240U of the lower insulating layer 240 on the cell region ACR.

Referring again to FIGS. 23 to 24B, a preliminary bit line layer PBL may be formed on the cell region ACR and the peripheral region PR. For example, forming the preliminary bit line layer PBL may include etching the polysilicon layer 210P, the ohmic layer 220P, the metal-containing pattern 230, and the lower insulating layer 240 using the first bit line mask pattern HM1 as an etch mask. Due to the etching process, an end of the preliminary bit line layer may be exposed.

The preliminary bit line layer PBL may include trench regions TR. The trench regions TR may be regions formed by the first openings OP1. The trenches TR may be spaced apart from each other in the second direction D2. Each of the trench regions TR may expose an upper surface 110U of the device isolation layer 110 on the cell region ACR.

A first capping layer 301P may be formed on the lower insulating layer 240. The first capping layer 301P may cover the exposed end of the preliminary bit line layer PBL. The first capping layer 301P may fill the trench regions TR and cover the upper surface 110U of the device isolation layer exposed by the trench regions TR.

A spacer layer SL may be formed on the first capping layer 301P. The spacer layer SL may fill the trench regions TR. For example, forming the spacer layer SL may include depositing a first insulating material on the first capping layer 301P and etching the first insulating material. For example, the etching process may be an anisotropic etching process.

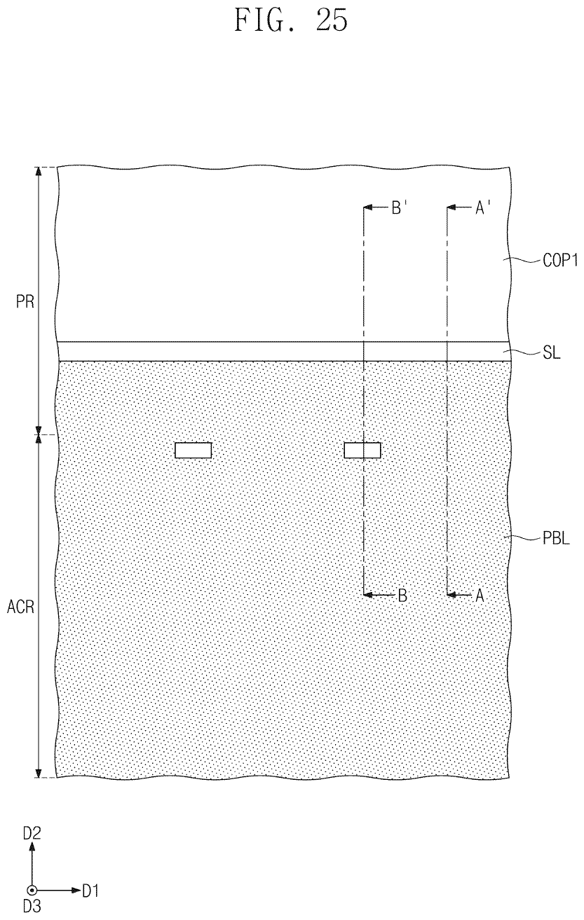

Referring again to FIGS. 25 to 26B, a first peripheral mask pattern COP1 may be formed on the peripheral region PR. The first peripheral mask pattern COP1 may be formed on the preliminary bit line layer PBL disposed on the peripheral region PR, and may cover the first capping layer 301P on the peripheral region PR and The spacer layer SL. The first peripheral mask pattern may expose the spacer layer SL filling the trench regions TR.

Referring again to FIGS. 27 to 28B, the spacer layer SL filling the trench regions TR may be removed. For example, removing the spacer layer SL may include etching the spacer layer SL filling the trench regions TR using the first peripheral mask pattern COP1 as an etch mask. Due to the etching process, an upper surface 301P_U of the first capping layer 301P on the trench regions TR may be exposed. Referring again to FIGS. 29 to 30B, a second capping layer 310P may be formed on the first capping layer 301P. The second capping layer 310P may extend onto the cell region ACR and the peripheral region PR. The second capping layer 310P may cover the exposed upper surface 301P_U of the first capping layer 301P.

Referring again to FIGS. 31 to 32B, a peripheral insulating layer 320 may be formed on the peripheral region PR. For example, forming the peripheral insulating layer 320 may include forming a second insulating material on the cell region ACR and the peripheral region PR and planarizing the second insulating material until an upper surface 310P_U of the second capping layer 310P is exposed.

The preliminary bit line protection pattern PP may fill the trench regions TR on the cell region ACR. The preliminary bit line protection pattern PP may be formed of the same material as the second insulating material forming the peripheral insulating layer 320. Forming the preliminary bit line protection pattern PP may include, for example, filling the trench region TR with a second insulating material and planarizing the second insulating material until the upper surface 310P_U of the second capping layer 310P is exposed.

Referring to FIGS. 37 to 38B, a second peripheral mask pattern COP2 may be formed on the peripheral region PR. The second peripheral mask pattern COP2 may be formed on the preliminary bit line layer PBL disposed on the peripheral region PR, and may cover the second capping layer 310P on the peripheral region PR and The spacer layer SL. The second peripheral mask pattern COP2 may expose an upper surface PP_U of the preliminary bit line protection pattern PP that fills the trench regions TR.

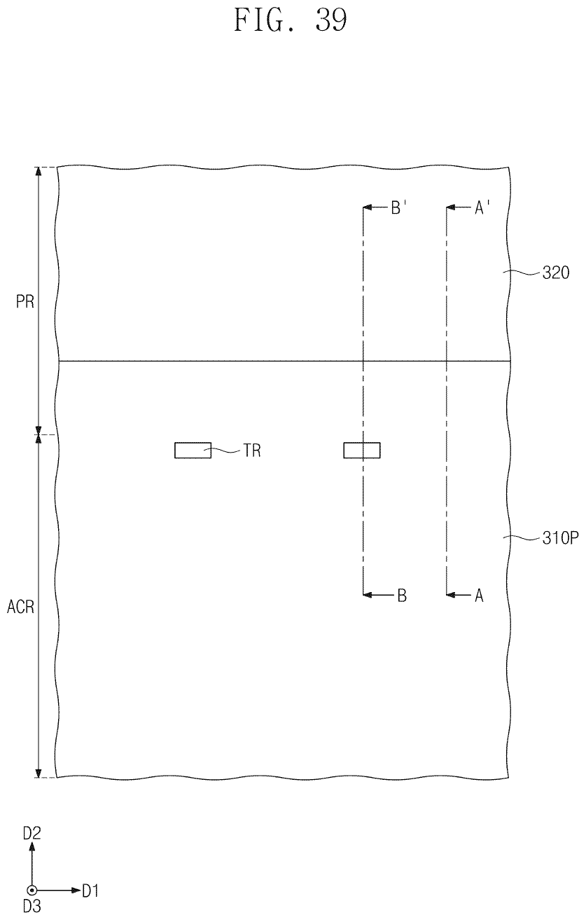

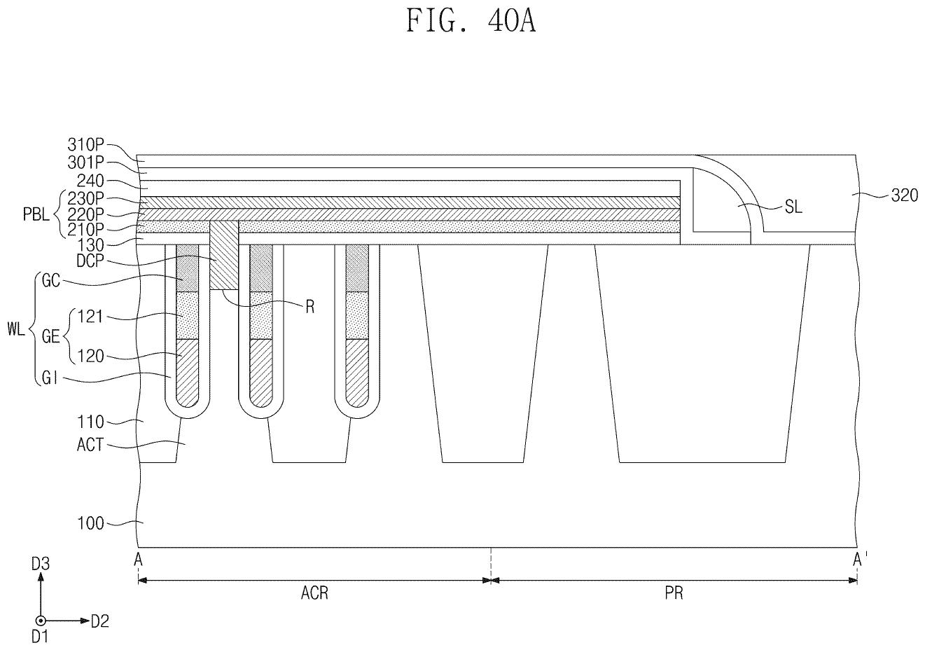

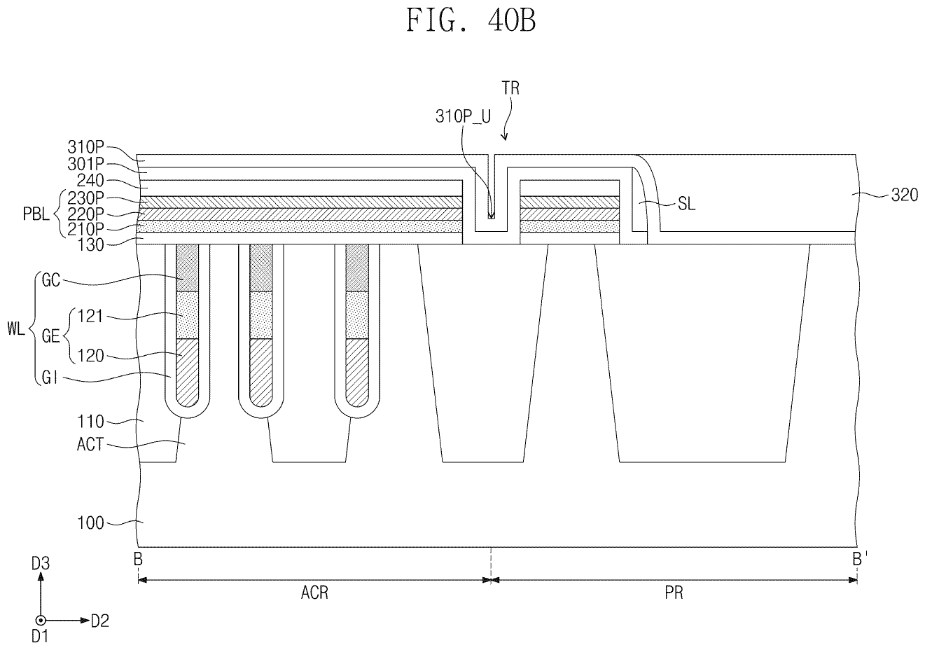

Referring to FIGS. 39 to 40B, the exposed preliminary bit line protection pattern PP may be removed. Removing the preliminary bit line protection pattern PP may include removing the preliminary bit line protection pattern PP by using the second peripheral mask pattern COP2 as an etch mask. By removing the preliminary bit line protection pattern PP, an upper surface 310P_U of the second capping layer 310P on the trench regions TR may be exposed. After the preliminary bit line protection pattern PP is removed, the second peripheral mask pattern COP2 may be removed.

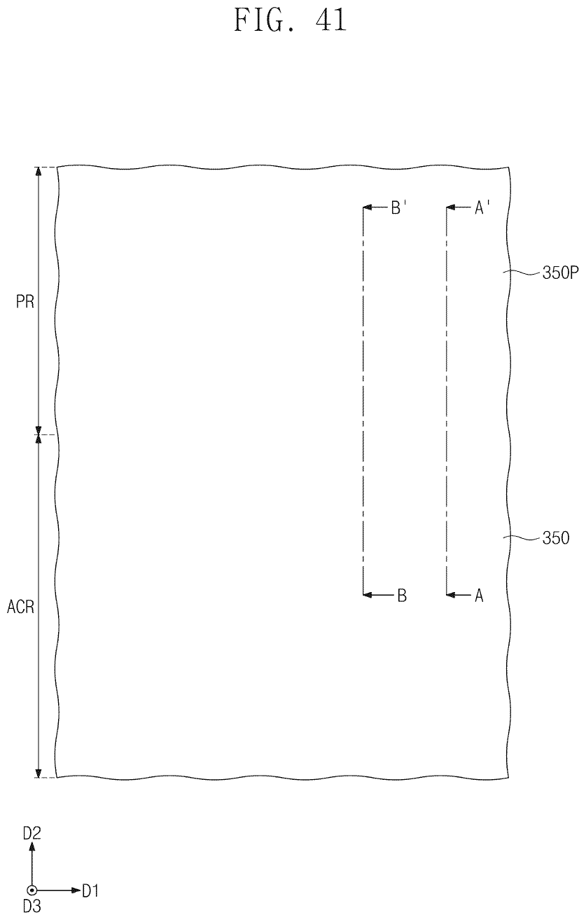

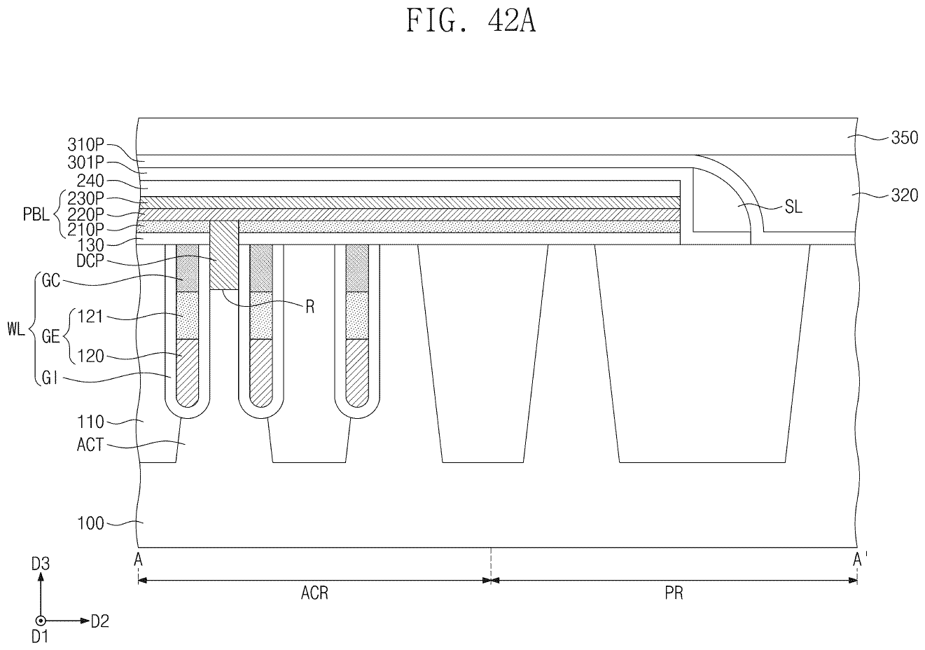

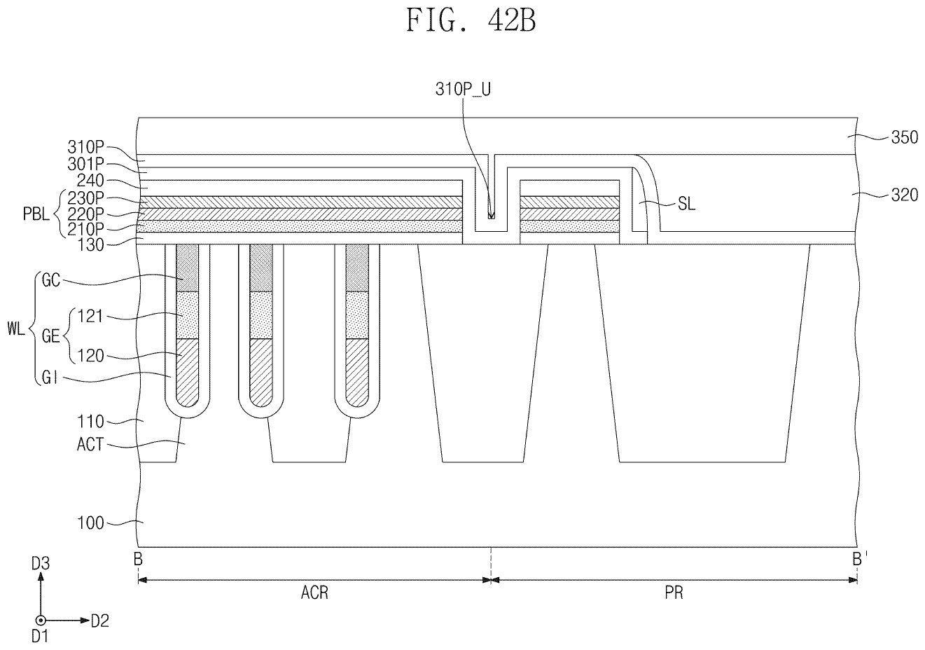

Referring to FIGS. 41 to 42B, a sacrificial layer 350 may be formed on the second capping layer 310P and the peripheral insulating layer 320. The sacrificial layer 350P may fill the trench regions TR. The sacrificial layer 350 may cover the exposed upper surface 310P_U of the second capping layer. For example, the sacrificial layer 350 may include silicon nitride.

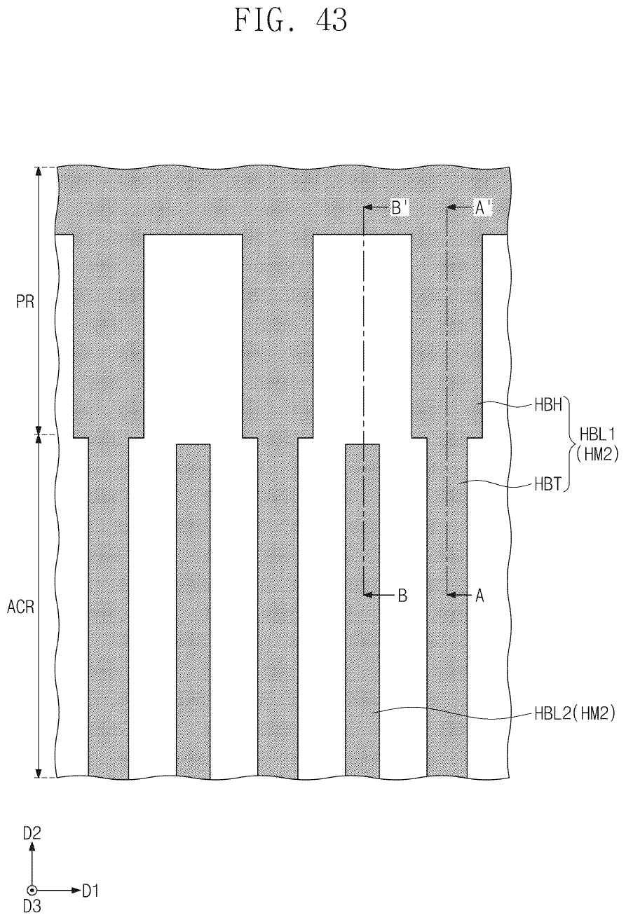

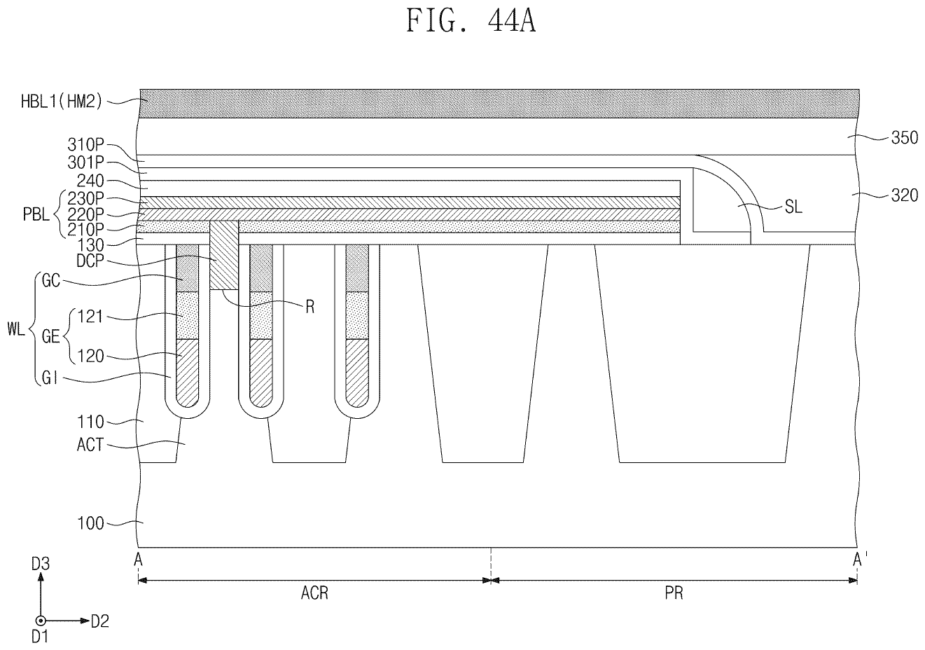

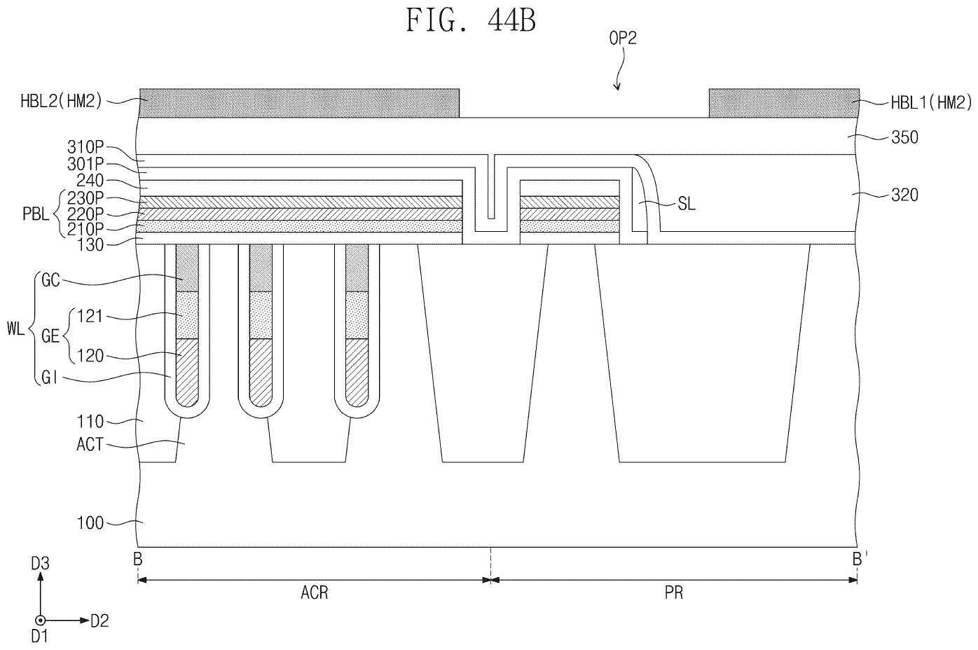

Referring to FIGS. 43 to 44B, a second bit line mask pattern HM2 may be formed on the sacrificial layer 350. The second bit line mask pattern HM2 may include a first mask pattern HBL1 defining a region where the first bit line is formed and a second mask pattern HBL2 defining a region where the second bit line is formed. For example, the second bit line mask pattern HBM2 may be a photoresist pattern.

The first mask pattern HBL1 may include a tail mask pattern HBT that defines a region where the bit line tail portion is formed, and a hammer mask pattern HBH that defines a region where the bit line hammer portion is formed.

The second mask pattern HBL2 may be offset from the hammer mask pattern HBH in the second direction D2. Additionally, the end portion of the second mask pattern HBL2 may be offset from the end portion of the tail mask pattern HBT in the second direction D2.

The second bit line mask pattern HM2 may include a second opening OP2. The second opening OP2 may mean a space between the first mask pattern and the second mask pattern in the second direction D2. The second opening OP may expose the sacrificial layer 350 corresponding to the trench region TR.

Referring again to FIGS. 17 to 20, bit lines BL may be formed on the substrate 100. The bit lines BL may include first bit lines BL1 and second bit lines BL2, and the first bit lines BL1 and the second bit lines BL2 may be spaced apart from each other in the first direction D1.

Each of the first bit lines BL1 may include a bit line tail portion BLT extending in the second direction D2 and a bit line hammer portion BLH connected to an end BLTE of the bit line tail portion BLT. For example, forming the first bit lines BL1 may include etching the preliminary bit line layer PBL using the first mask pattern HBL1 as an etch mask. More specifically, the bit line tail portion BLT may be formed using the tail mask pattern HBT as an etch mask, and the bit line hammer portion BLH may be formed using the hammer mask pattern BLH as an etch mask.

For example, forming the second bit lines BL2 may include etching the preliminary bit line layer PBL using the second mask pattern HBL2 as an etch mask. Each of the second bit lines BL2 may be offset from the bit line hammer portion BLH in the second direction D2. As a result, a short circuit phenomenon in which the second bit lines BL2 and the first bit lines BL1 are connected to each other may be reduced or prevented.

Through the etching process, the first capping pattern 301 and the second capping pattern 302 may be formed. For example, forming the first capping pattern 301 and the second capping pattern 302 may include etching the first capping layer 301P using the second bit line mask pattern HM2 as an etch mask.

Furthermore, a spacer pattern SP and a bit line protection pattern BLP may be formed through the etching process. For example, forming the spacer pattern SP may include etching the spacer layer SL using the second bit line mask pattern HM2 as an etch mask. For example, forming the bit line protection pattern BLP may include etching the sacrificial layer 350 filling the trench regions TR using the second bit line mask pattern HM2 as an etch mask.

According to the inventive concepts, as the first capping layer 301P, the second capping layer 310P, and the sacrificial layer 350 surround an end of each of the preliminary bit lines, in the etching process of forming the second bit lines BL2, thereby protecting the preliminary bit line layer PBL.

Additionally, the first capping layer, the second capping layer, and the sacrificial layer may all be silicon nitride, and thus oxygen radicals may not be generated during the etching process. As a result, damage to the preliminary bit line layer PBL may also be reduced or prevented.

That is, according to the inventive concepts, the second bit lines BL2 may be formed without being damaged, and thus reliability of the semiconductor device may be improved and a fabricating process with improved yield may be provided.

Bit line spacers 400 may be formed along side surfaces of the bit lines BL. The bit line spacer 400 may be formed to surround the second capping pattern 302 and the bit line protection pattern BLP.

Storage node contacts BC may be formed between the first bit lines BL1 and the second bit lines BL2. For example, forming the storage node contacts BC may include forming a preliminary contact layer between the first bit lines BL1 and the second bit lines BL2, forming the preliminary contact layer between the first bit lines BL1 and the second bit lines BL2, planarizing the preliminary contact layer until an upper surface of the capping pattern is exposed, and patterning the preliminary contact layer.

Other fabricating methods may be substantially the same as the method of fabricating the semiconductor device described with reference to FIGS. 23 to 36B.

Referring again to FIGS. 17 to 20, semiconductor devices according to some example embodiments of the inventive concepts will be described.

Bit lines BL may be disposed on the cell region ACR and the peripheral region PR of the substrate 100. The bit lines BL may be disposed on the insulating layer 130. The bit lines BL may cross the word lines WL. The bit lines BL may extend in the second direction D2 and may be spaced apart from each other in the first direction D1. The bit lines BL may include first bit lines BL1 and second bit lines BL2 arranged alternately in the second direction D1.

The first bit lines BL1 may include a bit line tail portion BLT extending in the second direction D2 and a bit line hammer portion BLH connected to an end of the bit line tail portion BLT. The bit line tail portion BLT may be disposed on the cell region ACR, and the bit line hammer portion BLH may be disposed on the peripheral region PR. A width BLH_W of the bit line hammer portion BLH in the first direction D1 may be greater than a width BLT_W of the bit line tail portion BLT in the first direction D1.

The second bit lines BL2 may be disposed on the cell region ACR. Each of the second bit lines BL2 may be offset from the bit line hammer portion BLH in the second direction D2. Furthermore, each of the second bit lines BL2 may be offset from the end BLTE of the bit line tail portion BLT in the second direction D2. A width BL2_W of each of the second bit lines BL2 in the first direction D1 may be smaller than the width BLH_W of the bit line hammer portion BLH in the first direction D1.

A lower insulating layer 240 may be disposed on the bit lines BL. The lower insulating layer 240 may extend in the second direction along an upper surface of the bit lines BL. Among the lower insulating layers 240, the lower insulating layer covering an upper surface BL1_U of the first bit lines BL1 may extend to the cell region ACR and the peripheral region PR. The lower insulating layer 240 covering the upper surfaces BL1_U of the first bit lines BL1 may cover upper surfaces of the bit line tail portion BLT and the bit line hammer portion BLH. Among the lower insulating layers 240, the lower insulating layer 240 covering the upper surface BL2_U of the second bit lines BL2 may be disposed on the cell region ACR.

A first capping pattern 301 may be disposed on the lower insulating layer 240 covering the first bit line BL1. The first capping pattern 301 may include an first upper capping pattern 301a, a lower first lower capping pattern 301b, and a first connection capping pattern 301c connecting the first upper capping pattern 301a and the lower first lower capping pattern 301b. The first upper capping pattern 301a may be disposed on the lower insulating layer 240, and may be disposed on the cell region ACR and the peripheral region PR. The lower first lower capping pattern 301b may be disposed on an upper surface of the device isolation layer 110 and may be disposed on the peripheral region PR. The first upper capping pattern 301a and the first lower capping pattern 301b may have a step in the third direction D3. The first connection capping pattern 301c may connect the first upper capping pattern 301a and the lower first lower capping pattern 301b and may surround the bit line hammer portion BLH. The first capping pattern (e.g., the connected first capping pattern) 301 may surround an end BLHE of the bit line hammer portion BLH. For example, the first capping pattern 301 may be silicon nitride.

A second capping pattern 302 may be disposed on the lower insulating layer 240 covering the second bit lines BL2. The second capping pattern 302 may include a second upper capping pattern 302a, a second lower capping pattern 302b, and a second connection capping pattern 302c connecting the second upper capping pattern 302a and the second lower capping pattern 302b. The second upper capping pattern 302a may be disposed on the lower insulating layer 240 and may be disposed on the cell region ACR. The second lower capping pattern 302b may be disposed on the device isolation layer 110 and may be disposed on the cell region ACR. The second upper capping pattern 302a and the second lower capping pattern 302b may have a step in the third direction D3. The second connection capping pattern 302c may connect the second upper capping pattern 302a and the second lower capping pattern 302b, and may surround each end BL2_E of the second bit lines BL2. For example, the second capping pattern 302 may be silicon nitride.

A spacer pattern SP may be disposed on the peripheral region PR and may be disposed on the lower first capping pattern 301 (e.g., the lower first capping pattern). The spacer pattern SP may surround the first connection capping pattern 301c and the end BLHE of the bit line hammer portion BLH. For example, the spacer pattern SP may include silicon oxide.

A third capping pattern 311 may be disposed on the peripheral region PR and on the spacer pattern SP. The third capping pattern 311 may be in contact with the lower first lower capping pattern 301b. For example, the third capping pattern 311 may be silicon nitride.

A fourth capping pattern 312 may be disposed on the second capping pattern 302 (e.g., lower second capping pattern) and may be disposed on the cell region ACR. For example, the fourth capping pattern 312 may be silicon nitride.

Referring to FIG. 20, a bit line protection pattern BLP may be disposed on the fourth capping pattern 312. The bit line protection pattern BLP may cover the second connection capping pattern 302c and each end BL2_E of the second bit lines BL2. The bit line protection pattern BLP may be offset from the bit line hammer portion BLH in the second direction D2.

A width BLP_W of the bit line protection pattern BLP in the first direction D1 may be smaller than the maximum width SP_W of the spacer pattern SP in the first direction D1. A width BLP_H of the bit line protection pattern BLP in the second direction D2 may be smaller than a separation distance D between the end BL2_E of the second bit line and the bit line hammer portion BLH in the second direction D2. The width BLP_H of the bit line protection pattern BLP in the second direction D2 may be smaller than a width 312H of the fourth capping pattern 312 in the second direction D2, and may be smaller than the width 302H of the second capping pattern 302 in the second direction D2. Additionally, a width 312H of the fourth capping pattern 312 in the second direction D2 may be smaller than the width 302H of the second capping pattern 302 in the second direction D2. The bit line protection pattern BLP may include a material different from the spacer pattern SP, and may include silicon nitride, for example. The bit line protection pattern BLP may not include silicon oxide.

Other structures may be substantially the same as the semiconductor devices described with reference to FIGS. 17 to 20.

According to the inventive concepts, the bit lines may include the first bit lines and the second bit lines, and may include the bit line protection pattern surrounding the ends of the second bit lines. Through the bit line protection pattern, the ends of the second bit lines may not be damaged during the etching process for forming the bit lines. As a result, the operating characteristics and reliability of semiconductor devices may be improved, and the fabricating process for semiconductor devices with improved yield may be provided.

While embodiments are described above, a person skilled in the art may understand that many modifications and variations are made without departing from the spirit and scope of the inventive concepts defined in the following claims. Accordingly, the example embodiments of the inventive concepts should be considered in all respects as illustrative and not restrictive, with the spirit and scope of the inventive concepts being indicated by the appended claims.

What is claimed is:

1. A semiconductor device comprising:
a substrate including a cell region and a peripheral region;
word lines extending in a first direction on the cell region;
bit lines extending across the word lines in a second direction, the second direction intersecting the first direction, and including
first bit lines and second bit lines arranged alternately in the first direction,
each of the first bit lines including
a bit line tail portion extending in the second direction, and
a bit line hammer portion connected to an end of the bit line tail portion;
a spacer pattern surrounding the bit line hammer portion on the peripheral region;
a bit line protection pattern surrounding each end of the second bit lines in the cell region; and
a bit line spacer extending in the second direction along each side surface of the bit lines,
wherein the bit line spacer extends on side surfaces of the spacer pattern and the bit line protection pattern in the second direction, and
a width of the bit line protection pattern in the first direction is smaller than a maximum width of the spacer pattern in the first direction.

2. The semiconductor device of claim 1, wherein a width of the bit line protection pattern in the first direction is smaller than a width of the bit line hammer portion in the first direction.

3. The semiconductor device of claim 1, wherein each of the second bit lines is offset from the bit line hammer portion in the second direction.

4. The semiconductor device of claim 1, wherein the spacer pattern includes
a first portion and a second portion facing each other in the first direction and extending in the second direction, and
a third portion extending in the first direction and connecting the first portion and the second portion, and
wherein the third portion covers an end of the bit line hammer portion.

5. The semiconductor device of claim 4, wherein a width of the first portion in the first direction and a width of the second portion in the first direction are different from each other.

6. The semiconductor device of claim 4, wherein a width of the third portion in the second direction is greater than a width of the bit line protection pattern in the second direction.

7. The semiconductor device of claim 4, wherein a width of the third portion in the first direction is greater than a width of the bit line protection pattern in the first direction.

8. The semiconductor device of claim 4, wherein the third portion has a curved shape when viewed in a plan view.

9. The semiconductor device of claim 1, further comprising:
a first capping pattern between the bit line hammer portion and the spacer pattern; and
a second capping pattern between each of the second bit lines and the bit line protection pattern,
wherein a width of the second capping pattern in the second direction is greater than a width of the bit line protection pattern in the second direction.

10. The semiconductor device of claim 1, further comprising:
a third capping pattern on the spacer pattern; and
a fourth capping pattern on the bit line protection pattern,
wherein a width of the fourth capping pattern in the second direction is smaller than a width of the bit line protection pattern in the second direction.

11. The semiconductor device of claim 1, wherein the bit line protection pattern does not include oxide.

12. The semiconductor device of claim 1, wherein the bit line protection pattern is offset from the bit line hammer portion in the second direction.

13. The semiconductor device of claim 1, wherein the spacer pattern and the bit line protection pattern include the same material.

14. A semiconductor device comprising:
a substrate including a cell region and a peripheral region;
word lines extending in a first direction on the cell region;
bit lines extending across the word lines in a second direction, the second direction intersecting the first direction, and including
first bit lines and second bit lines arranged alternately in the first direction,
each of the first bit lines including a bit line hammer portion on the peripheral region;
a first capping pattern surrounding each of the first bit lines on the peripheral region;
a second capping pattern surrounding each of the second bit lines on the cell region;
a spacer pattern on the first capping pattern in the peripheral region and surrounding an end of the bit line hammer portion; and
a bit line protection pattern on the second capping pattern in the cell region and surrounding each end of the second bit lines,
wherein the first capping pattern and the second capping pattern include a first same material,
the bit line protection pattern and the spacer pattern include a second same material, and
the bit line protection pattern is offset from the spacer pattern in the second direction.

15. The semiconductor device of claim 14, wherein the bit line protection pattern and the spacer pattern include one or more of silicon oxide and silicon nitride.

16. The semiconductor device of claim 14, further comprising a bit line spacer extending in the second direction along each side surface of the bit lines,
wherein the bit line spacer covers side surfaces of the bit line protection pattern and the spacer pattern.

17. The semiconductor device of claim 14, wherein a width of the second capping pattern in the second direction is greater than a width of the bit line protection pattern in the second direction.

18. The semiconductor device of claim 17, wherein a width of the bit line protection pattern in the second direction is smaller than a separation distance between an end of the second bit lines and the bit line hammer portion in the second direction when viewed in a plan view.

19. A semiconductor device comprising:
a substrate including a cell region and a peripheral region;
word lines extending in a first direction on the cell region;
bit lines extending across the word lines in a second direction, the second direction intersecting the first direction, and including
first bit lines and second bit lines arranged alternately in the first direction,
each of the first bit lines including
a bit line tail portion extending in the second direction, and
a bit line hammer portion connected to an end of the bit line tail portion;
bit line contacts on the cell region and connected to corresponding bit lines among the bit lines;
a first capping pattern surrounding each of the first bit lines on the peripheral region;
a second capping pattern surrounding each of the second bit lines on the cell region;
a spacer pattern on the first capping pattern in the peripheral region and surrounding an end of the bit line hammer portion;
a bit line protection pattern on the second capping pattern in the cell region and surrounding each end of the second bit lines; and
a bit line spacer extending in the second direction along each side surface of the bit lines,
wherein the bit line protection pattern is offset from the spacer pattern in the second direction,
a width of the bit line protection pattern in the first direction is smaller than a width of the spacer pattern in the first direction, and
a width of the bit line protection pattern in the second direction is smaller than a width of the second capping pattern in the second direction.

20. The semiconductor device of claim 19, wherein the bit line protection pattern and the spacer pattern include the same material.
